(19) United States
(12) Patent Application Publication
(10) Pub. No.: US 2016/0054561 A1
(43) Pub. Date: Feb. 25, 2016

(54) DISPLAY APPARATUS INCORPORATING EDGE SEALS FOR REDUCING MOISTURE INGRESS

(71) Applicant: Pixtronix, Inc., San Diego, CA (US)

(72) Inventors: Wilhelmus Adrianus De Groot, Palo Alto, CA (US); Sriram Akella, Santa Clara, CA (US)

(21) Appl. No.: 14/464,402

(22) Filed: Aug. 20, 2014

(51) Int. Cl. G02B 26/02; G02B 27/00; B81B 7/00; G09G 3/34

(52) U.S. Cl. CPC G02B 26/02; G09G 3/3433; G02B 27/0006; B81B 7/0038; G09G 2310/0262; B81B 2201/047

(57) ABSTRACT

This disclosure provides systems, methods, and apparatus for protecting a display device from moisture ingress. A display device can be formed from two opposing substrates. Moisture-impervious walls can be formed around the perimeters of viewing areas included on the substrates. At least one of the substrates can include a second perimeter wall and a trench defined by the two perimeter walls. The trench can be filled with epoxy, and the substrates can be brought together such that the perimeter walls align and are brought into contact with one another. The epoxy is cured, trapped within the perimeter trench, bonding the substrates to one another and forming a substantially moisture impervious seal.

### TECHNICAL FIELD

This disclosure relates to the field of imaging displays, and in particular to image formation processes for field sequential color (FSC) displays.

### DESCRIPTION OF THE RELATED TECHNOLOGY

Electromechanical systems (EMS) devices include devices having electrical and mechanical elements, such as actuators, optical components (such as mirrors, shutters, and/or optical film layers) and electronics. EMS devices can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of deposited material layers, or that add layers to form electrical and electromechanical devices.

EMS-based display apparatus have been proposed that include display elements that modulate light by selectively moving a light blocking component into and out of an optical path through an aperture defined through a light blocking layer. Doing so selectively passes light from a backlight or reflects light from the ambient or a front light to form an image.

### SUMMARY

The systems, methods and devices of the disclosure each have several innovative aspects, no single one of which is solely responsible for the desirable attributes disclosed herein.

One innovative aspect of the subject matter described in this disclosure can be implemented in an apparatus. The apparatus includes a first substrate including a first planar surface. The first planar surface includes a first image viewing area. The apparatus includes a first perimeter wall formed around a perimeter of the first image viewing area and extending away from the first planar surface. The apparatus includes a second perimeter wall formed around a perimeter of the first image viewing area and extending away from the first planar surface. The first and second perimeter walls define a first perimeter trench surrounding the first image viewing area of the first substrate. The apparatus includes a second substrate comprising a second planar surface opposing the first planar surface of the first substrate and including a second image viewing area aligned with the first image viewing area of the first substrate. The apparatus includes a third perimeter wall formed around a perimeter of the second image viewing area and extending away from the second planar surface. The apparatus includes an adhesive material filling the first perimeter trench and bonding the first substrate to the second substrate.

In some implementations, the first perimeter wall and the second perimeter wall include a cured polymer material coated with a material that is substantially impervious to moisture. In some implementations, the first perimeter wall and second perimeter wall include one or more of amorphous silicon, aluminum, titanium, and a dielectric material. In some implementations, the apparatus includes a plurality of microelectromechanical systems (MEMS) display elements fabricated on the first substrate. The first perimeter wall and the MEMS display elements can be formed of at least one common material.

In some implementations, the apparatus includes a fourth perimeter wall on the second substrate, around the perimeter of the second image viewing area and extending away from the second planar surface. The third perimeter wall and the fourth perimeter wall can define a second perimeter trench surrounding the second image viewing area of the second substrate. The first perimeter trench of the first substrate can be aligned with the second perimeter trench of the second substrate and the adhesive material also can fill the second perimeter trench.

In some implementations, the apparatus can include a fifth perimeter wall on the first substrate, spaced away from the second perimeter wall and extending away from the first planar surface. The second and fifth perimeter walls can define a third perimeter trench surrounding the first image viewing area of the first substrate. The apparatus also can include a sixth perimeter wall on the second substrate, spaced away from the fourth perimeter wall and extending away from the first planar surface. The fourth and sixth perimeter walls can define a fourth perimeter trench surrounding the first image viewing area of the first substrate. The third perimeter trench on the first substrate can be aligned with the fourth perimeter trench on the second substrate. A desiccant material can fill the third and fourth perimeter trenches.

In some implementations, each of the first, second, and third perimeter walls can have a height in the range of about 4 microns to about 10 microns. In some implementations, each of the first, second, and third perimeter walls can have a width in the range of about 30 microns to about 60 microns. In some implementations, the first perimeter trench can have a width in the range of about 300 microns to about 1000 microns.

In some implementations, the apparatus can also include a display and a processor that is capable of communicating with the display. The processor can be capable of processing image data. The apparatus also can include a memory device that is capable of communicating with the processor.

In some implementations, the apparatus can include a driver circuit capable of sending at least one signal to the display and a controller capable of sending at least a portion of the image data to the driver circuit. The apparatus also can include an image source module capable of sending the image data to the processor. The image source module can include at least one of a receiver, transceiver, and transmitter. In some implementations, the apparatus also can include an input device capable of receiving input data and communicating the input data to the processor.

Another innovative aspect of the subject matter described in this disclosure can be implemented in a method of manufacturing a display apparatus. The method includes depositing at least one layer of polymer material over a first substrate. The method includes patterning the at least one layer of polymer material deposited over the first substrate to define a first perimeter wall extending outwards from a surface of the first substrate and surrounding a first image viewing area on the first substrate and a second perimeter wall extending outwards from the surface of the first substrate and surrounding the first image viewing area. The first and second perimeter walls define a first perimeter trench surrounding the first image viewing area of the first substrate. The method includes depositing a first layer of structural material over the at least one layer of polymer material such that the structural material coats the surfaces of the first and second perimeter walls. The structural material is substantially impervious to moisture. The method includes depositing at least one layer of polymer material over a second substrate. The method includes patterning the at least one layer of polymer material deposited over the second substrate to define a third perimeter wall extending outwards from a surface of the second substrate and surrounding a second image viewing area on the second substrate. The method includes depositing a second layer of structural material over the at least one layer of polymer material deposited over the second substrate such that the structural material coats the surfaces of the third perimeter wall. The structural material is substantially impervious to moisture. The method includes positioning the first substrate and the second substrate such that the first and second perimeter walls of the first substrate are opposed to the third perimeter wall of the second substrate. The method includes bonding the first substrate to the second substrate by filling the first perimeter trench with an adhesive material.

In some implementations, the method can include forming a plurality of display elements over the first viewing area of the first substrate. In some implementations, the method can include patterning the at least one layer of polymer material deposited over the second substrate to define a fourth perimeter wall extending outwards from the surface of the second substrate and surrounding the second image viewing area on the second substrate. The third perimeter wall and the fourth perimeter wall can define a second perimeter trench surrounding the second image viewing area. The method also can include positioning the first substrate and the second substrate such that the first perimeter trench is aligned with the second perimeter trench and filling the first perimeter trench and the second perimeter trench with the adhesive material.

In some implementations, the method can include patterning the at least one layer of polymer material deposited over the first substrate to define a fifth perimeter wall extending outwards from the surface of the first substrate and surrounding the first image viewing area on the first substrate. The fifth perimeter wall and the second perimeter wall can define a third perimeter trench surrounding the first image viewing area. The method can include patterning the at least one layer of polymer material deposited over the second substrate to define a sixth perimeter wall extending outwards from the surface of the second substrate and surrounding the second image viewing area on the second substrate. The sixth perimeter wall and the fourth perimeter wall can define a fourth perimeter trench surrounding the second image viewing area. The method also can include positioning the first substrate and the second substrate such that the third perimeter trench is aligned with the fourth perimeter trench and filling the third perimeter trench and the fourth perimeter trench with a desiccant.

Details of one or more implementations of the subject matter described in this specification are set forth in the accompanying drawings and the description below. Although the examples provided in this summary are primarily described in terms of electromechanical systems (EMS) based displays, the concepts provided herein may apply to other types of displays, such as liquid crystal displays (LCDs), organic light-emitting diode (OLED) displays, electrophoretic displays, and field emission displays, as well as to other non-display EMS devices, such as EMS microphones, sensors, and optical switches. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1A shows a schematic diagram of an example direct-view microelectromechanical systems (MEMS) based display apparatus.

FIG. 1B shows a block diagram of an example host device.

FIGS. 2A and 2B show views of an example dual actuator shutter assembly.

FIG. 3 shows a cross sectional view of an example display apparatus incorporating shutter-based light modulators.

FIGS. 4A-4E show various views of an example display incorporating opposing substrates with perimeter walls.

FIGS. 5A-5C show various views of a second example display incorporating opposing substrates with perimeter walls.

FIGS. 6A-6C show various views of a third example display incorporating opposing substrates with perimeter walls.

FIG. 7 shows a flow diagram of an example method for manufacturing a display apparatus.

FIGS. 8A-8F show cross-sectional views of stages of construction of an example display according to the manufacturing process shown in FIG. 7.

FIG. 9 shows a second example of a display that can be manufactured according to a process similar to the process shown in FIG. 7.

FIG. 10 shows a second example of a display that can be manufactured according to a process similar to the process shown in FIG. 7.

FIGS. 11 and 12 show system block diagrams of an example display device that includes a plurality of display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that can be configured to display an image, whether in motion (such as video) or stationary (such as still images), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, clocks, calculators, television monitors, flat panel displays, electronic reading devices (for example, e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, as well as non-EMS applications), aesthetic structures (such as display of images on a piece of jewelry or clothing) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

MEMS displays can incorporate shutter-based display elements positioned between two substrates. The substrates can be joined by a seal formed around the edges of the substrates. Some seals, such as those formed from epoxy, can be permeable to humidity, which can lead to reduced reliability or lifespan of the shutter-based light display elements. A display apparatus can be formed to be substantially impervious to moisture by bonding opposing substrates with an epoxy seal situated within a trench formed by substantially moisture-impervious walls located around the perimeters of viewing regions of the substrates. In some implementations, the walls can be formed using thin film deposition and patterning techniques. In some implementations, a trench is formed on only one substrate. In some implementations, a trench is formed on both substrates, such that each substrate can include a perimeter trench defined by inner and outer perimeter walls. The substrates are then brought together such that the perimeter walls align, with the trench or trenches filled with an epoxy. The epoxy can then be cured, substantially trapped within and filling the perimeter trenches.

The perimeter walls can be formed from or be coated with materials that are themselves substantially impervious to moisture. As such, the moisture that could enter the display is limited to moisture that passes through minimal gaps that may exist between opposing perimeter walls after the substrates are brought together and the epoxy is cured. That moisture must then pass through the epoxy, which is moisture resistant (though not impervious) and an inner set of walls. Together, these obstacles can reduce or substantially eliminate the passage of moisture through the seal. In some implementations, additional perimeter walls may be formed on one or both of the substrates to define additional trenches. The additional trenches can be filled with a desiccant material to further prevent moisture from passing through the seal.

Particular implementations of the subject matter described in this disclosure can be implemented to realize one or more of the following potential advantages. By incorporating perimeter walls that are formed from substantially moisture-impervious material, the amount of moisture that can pass through an edge seal into the display can be significantly reduced. Because moisture can interfere with the reliability of a display apparatus, the perimeter walls can help to improve the reliability and lifespan of the display. In some implementations, the perimeter walls can be formed during the same process used to form display elements over one or both of the substrates, which can simplify the manufacturing process. Because the perimeter walls can be deposited using high precision MEMS-based fabrication techniques, the thickness of the edge seal formed by the perimeter walls can be accurately controlled.

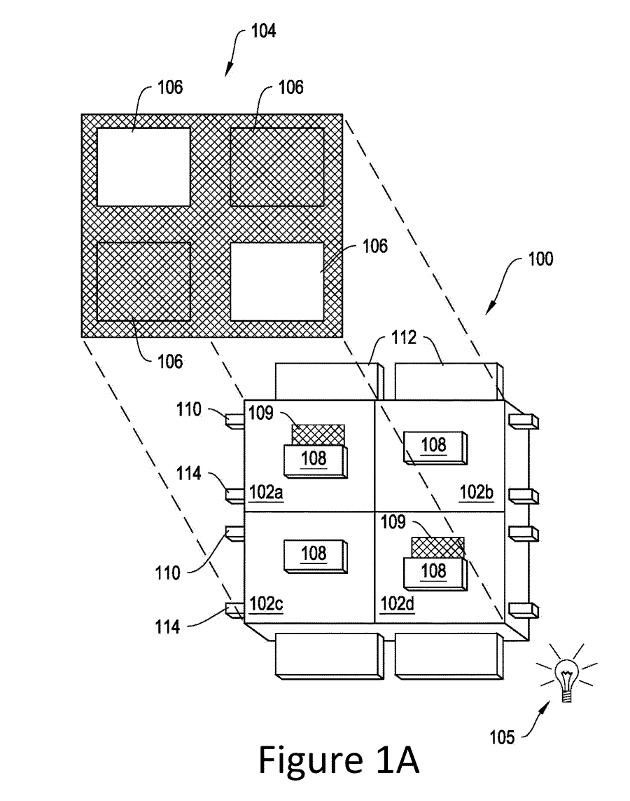

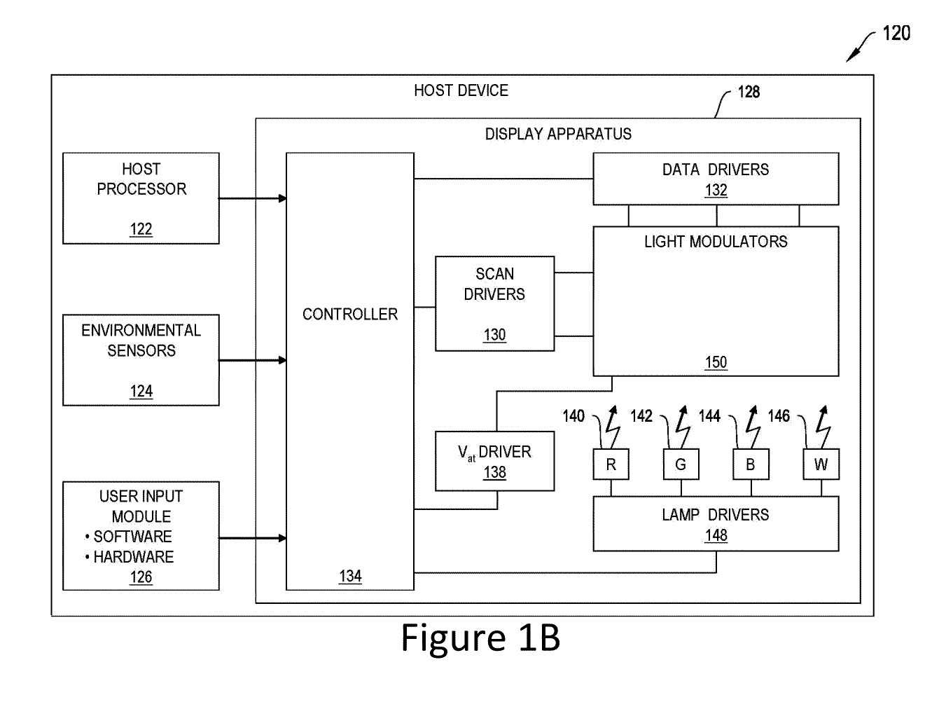

FIG. 1A shows a schematic diagram of an example direct-view MEMS-based display apparatus 100. The display apparatus 100 includes a plurality of light modulators 102a-102d (generally light modulators 102) arranged in rows and columns. In the display apparatus 100, the light modulators 102a and 102d are in the open state, allowing light to pass. The light modulators 102b and 102c are in the closed state, obstructing the passage of light. By selectively setting the states of the light modulators 102a-102d, the display apparatus 100 can be utilized to form an image 104 for a backlit display, if illuminated by a lamp or lamps 105. In another implementation, the apparatus 100 may form an image by reflection of ambient light originating from the front of the apparatus. In another implementation, the apparatus 100 may form an image by reflection of light from a lamp or lamps positioned in the front of the display, i.e., by use of a front light.

In some implementations, each light modulator 102 corresponds to a pixel 106 in the image 104. In some other implementations, the display apparatus 100 may utilize a plurality of light modulators to form a pixel 106 in the image 104. For example, the display apparatus 100 may include three color-specific light modulators 102. By selectively opening one or more of the color-specific light modulators 102 corresponding to a particular pixel 106, the display apparatus 100 can generate a color pixel 106 in the image 104. In another example, the display apparatus 100 includes two or more light modulators 102 per pixel 106 to provide a luminance level in an image 104. With respect to an image, a pixel corresponds to the smallest picture element defined by the resolution of image. With respect to structural components of the display apparatus 100, the term pixel refers to the combined mechanical and electrical components utilized to modulate the light that forms a single pixel of the image.

The display apparatus 100 is a direct-view display in that it may not include imaging optics typically found in projection applications. In a projection display, the image formed on the surface of the display apparatus is projected onto a screen or onto a wall. The display apparatus is substantially smaller than the projected image. In a direct view display, the user sees the image by looking directly at the display apparatus, which contains the light modulators and optionally a backlight or front light for enhancing brightness and/or contrast seen on the display.

Direct-view displays may operate in either a transmissive or reflective mode. In a transmissive display, the light modulators filter or selectively block light which originates from a lamp or lamps positioned behind the display. The light from the lamps is optionally injected into a lightguide or backlight so that each pixel can be uniformly illuminated. Transmissive direct-view displays are often built onto transparent or glass substrates to facilitate a sandwich assembly arrangement where one substrate, containing the light modulators, is positioned over the backlight.

Each light modulator 102 can include a shutter 108 and an aperture 109. To illuminate a pixel 106 in the image 104, the shutter 108 is positioned such that it allows light to pass through the aperture 109 towards a viewer. To keep a pixel 106 unlit, the shutter 108 is positioned such that it obstructs the passage of light through the aperture 109. The aperture 109 is defined by an opening patterned through a reflective or light-absorbing material in each light modulator 102.

The display apparatus also includes a control matrix connected to the substrate and to the light modulators for controlling the movement of the shutters. The control matrix includes a series of electrical interconnects (such as interconnects 110, 112 and 114), including at least one write-enable interconnect 110 (also referred to as a scan-line interconnect) per row of pixels, one data interconnect 112 for each column of pixels, and one common interconnect 114 providing a common voltage to all pixels, or at least to pixels from both multiple columns and multiples rows in the display apparatus 100. In response to the application of an appropriate voltage (the write-enabling voltage, V_{WE}), the write-enable interconnect 110 for a given row of pixels prepares the pixels in the row to accept new shutter movement instructions. The data interconnects 112 communicate the new movement instructions in the form of data voltage pulses. The data voltage pulses applied to the data interconnects 112, in some implementations, directly contribute to an electrostatic movement of the shutters. In some other implementations, the data voltage pulses control switches, such as transistors or other non-linear circuit elements that control the application of separate actuation voltages, which are typically higher in magnitude than the data voltages, to the light modulators 102. The application of these actuation voltages results in the electrostatic driven movement of the shutters 108.

FIG. 1B shows a block diagram of an example host device 120 (i.e., cell phone, smart phone, PDA, MP3 player, tablet, e-reader, netbook, notebook, watch, etc.). The host device 120 includes a display apparatus 128, a host processor 122, environmental sensors 124, a user input module 126, and a power source.

The display apparatus 128 includes a plurality of scan drivers 130 (also referred to as write enabling voltage sources), a plurality of data drivers 132 (also referred to as data voltage sources), a controller 134, common drivers 138, lamps 140-146, lamp drivers 148 and an array 150 of display elements, such as the light modulators 102 shown in FIG. 1A. The scan drivers 130 apply write enabling voltages to scan-line interconnects 110. The data drivers 132 apply data voltages to the data interconnects 112.

In some implementations of the display apparatus, the data drivers 132 are configured to provide analog data voltages to the array 150 of display elements, especially where the luminance level of the image 104 is to be derived in analog fashion. In analog operation, the light modulators 102 are designed such that when a range of intermediate voltages is applied through the data interconnects 112, there results a range of intermediate open states in the shutters 108 and therefore a range of intermediate illumination states or luminance levels in the image 104. In other cases, the data drivers 132 are configured to apply only a reduced set of 2, 3 or 4 digital voltage levels to the data interconnects 112. These voltage levels are designed to set, in digital fashion, an open state, a closed state, or other discrete state to each of the shutters 108.

The scan drivers 130 and the data drivers 132 are connected to a digital controller circuit 134 (also referred to as the controller 134). The controller sends data to the data drivers 132 in a mostly serial fashion, organized in sequences, which in some implementations may be predetermined, grouped by rows and by image frames. The data drivers 132 can include series to parallel data converters, level shifting, and for some applications digital to analog voltage converters.

The display apparatus optionally includes a set of common drivers 138, also referred to as common voltage sources. In some implementations, the common drivers 138 provide a DC common potential to all display elements within the array 150 of display elements, for instance by supplying voltage to a series of common interconnects 114. In some other implementations, the common drivers 138, following commands from the controller 134, issue voltage pulses or signals to the array 150 of display elements, for instance global actuation pulses which are capable of driving and/or initiating simultaneous actuation of all display elements in multiple rows and columns of the array 150.

All of the drivers (such as scan drivers 130, data drivers 132 and common drivers 138) for different display functions are time-synchronized by the controller 134. Timing commands from the controller coordinate the illumination of red, green, blue and white lamps (140, 142, 144 and 146 respectively) via lamp drivers 148, the write-enabling and sequencing of specific rows within the array 150 of display elements, the output of voltages from the data drivers 132, and the output of voltages that provide for display element actuation. In some implementations, the lamps are light emitting diodes (LEDs).

The controller 134 determines the sequencing or addressing scheme by which each of the shutters 108 can be re-set to the illumination levels appropriate to a new image 104. New images 104 can be set at periodic intervals. For instance, for video displays, the color images 104 or frames of video are refreshed at frequencies ranging from 10 to 300 Hertz (Hz). In some implementations the setting of an image frame to the array 150 is synchronized with the illumination of the lamps 140, 142, 144 and 146 such that alternate image frames are illuminated with an alternating series of colors, such as red, green, blue and white. The image frames for each respective color are referred to as color subframes. In this method, referred to as the field sequential color method, if the color subframes are alternated at frequencies in excess of 20 Hz, the human brain will average the alternating frame images into the perception of an image having a broad and continuous range of colors. In alternate implementations, four or more lamps with primary colors can be employed in display apparatus 100, employing primaries other than red, green, blue and white.

In some implementations, where the display apparatus 100 is designed for the digital switching of shutters 108 between open and closed states, the controller 134 forms an image by the method of time division grayscale, as previously described. In some other implementations, the display apparatus 100 can provide grayscale through the use of multiple shutters 108 per pixel.

In some implementations, the data for an image 104 state is loaded by the controller 134 to the display element array 150 by a sequential addressing of individual rows, also referred to as scan lines. For each row or scan line in the sequence, the scan driver 130 applies a write-enable voltage to the write enable interconnect 110 for that row of the array 150, and subsequently the data driver 132 supplies data voltages, corresponding to desired shutter states, for each column in the selected row. This process repeats until data has been loaded for all rows in the array 150. In some implementations, the sequence of selected rows for data loading is linear, proceeding from top to bottom in the array 150. In some other implementations, the sequence of selected rows is pseudo-randomized, in order to minimize visual artifacts. And in some other implementations, the sequencing is organized by blocks, where, for a block, the data for only a certain fraction of the image 104 state is loaded to the array 150, for instance by addressing only every 5^{th} row of the array 150 in sequence.

In some implementations, the process for loading image data to the array 150 is separated in time from the process of actuating the display elements in the array 150. In these implementations, the display element array 150 may include data memory elements for each display element in the array 150 and the control matrix may include a global actuation interconnect for carrying trigger signals, from common driver 138, to initiate simultaneous actuation of shutters 108 according to data stored in the memory elements.

In alternative implementations, the array 150 of display elements and the control matrix that controls the display elements may be arranged in configurations other than rectangular rows and columns. For example, the display elements can be arranged in hexagonal arrays or curvilinear rows and columns. In general, as used herein, the term scan-line shall refer to any plurality of display elements that share a write-enabling interconnect.

The host processor 122 generally controls the operations of the host. For example, the host processor 122 may be a general or special purpose processor for controlling a portable electronic device. With respect to the display apparatus 128, included within the host device 120, the host processor 122 outputs image data as well as additional data about the host. Such information may include data from environmental sensors, such as ambient light or temperature; information about the host, including, for example, an operating mode of the host or the amount of power remaining in the host's power source; information about the content of the image data; information about the type of image data; and/or instructions for display apparatus for use in selecting an imaging mode.

The user input module 126 conveys the personal preferences of the user to the controller 134, either directly, or via the host processor 122. In some implementations, the user input module 126 is controlled by software in which the user programs personal preferences such as deeper color, better contrast, lower power, increased brightness, sports, live action, or animation. In some other implementations, these preferences are input to the host using hardware, such as a switch or dial. The plurality of data inputs to the controller 134 direct the controller to provide data to the various drivers 130, 132, 138 and 148 which correspond to optimal imaging characteristics.

An environmental sensor module 124 also can be included as part of the host device 120. The environmental sensor module 124 receives data about the ambient environment, such as temperature and or ambient lighting conditions. The sensor module 124 can be programmed to distinguish whether the device is operating in an indoor or office environment versus an outdoor environment in bright daylight versus an outdoor environment at nighttime. The sensor module 124 communicates this information to the display controller 134, so that the controller 134 can optimize the viewing conditions in response to the ambient environment.

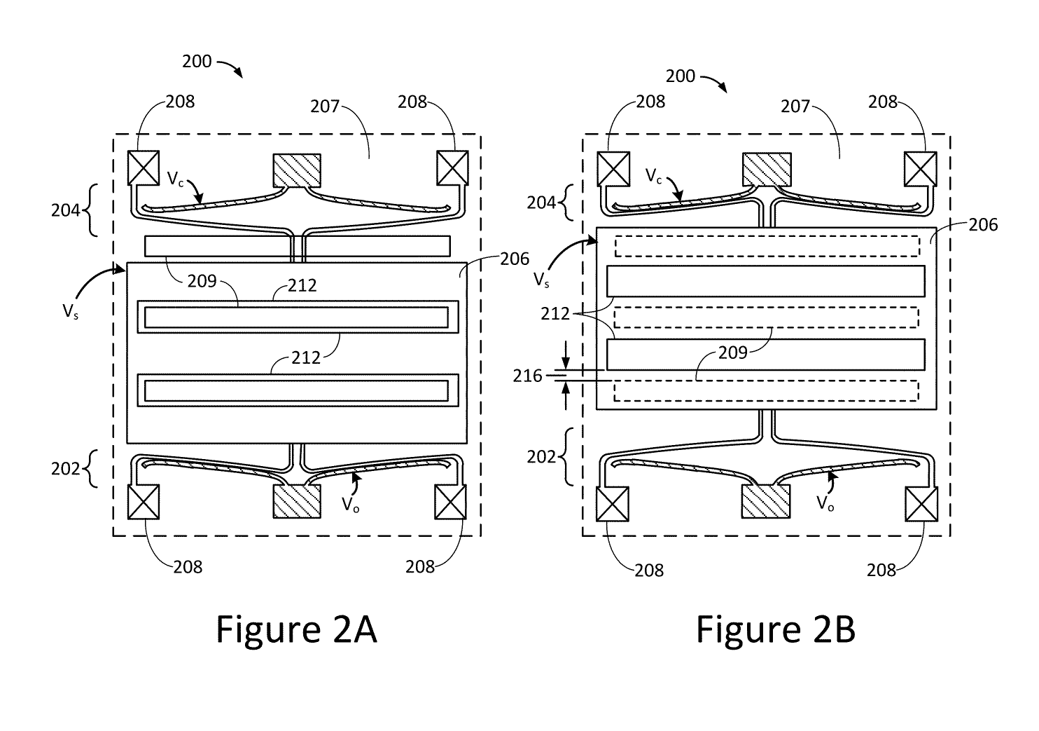

FIGS. 2A and 2B show views of an example dual actuator shutter assembly 200. The dual actuator shutter assembly 200, as depicted in FIG. 2A, is in an open state. FIG. 2B shows the dual actuator shutter assembly 200 in a closed state. In contrast to the shutter assembly 200, the shutter assembly 200 includes actuators 202 and 204 on either side of a shutter 206. Each actuator 202 and 204 is independently controlled. A first actuator, a shutter-open actuator 202, serves to open the shutter 206. A second opposing actuator, the shutter-close actuator 204, serves to close the shutter 206. Both of the actuators 202 and 204 are compliant beam electrode actuators. The actuators 202 and 204 open and close the shutter 206 by driving the shutter 206 substantially in a plane parallel to an aperture layer 207 over which the shutter is suspended. The shutter 206 is suspended a short distance over the aperture layer 207 by anchors 208 attached to the actuators 202 and 204. The inclusion of supports attached to both ends of the shutter 206 along its axis of movement reduces out of plane motion of the shutter 206 and confines the motion substantially to a plane parallel to the substrate.

The shutter 206 includes two shutter apertures 212 through which light can pass. The aperture layer 207 includes a set of three apertures 209. In FIG. 2A, the shutter assembly 200 is in the open state and, as such, the shutter-open actuator 202 has been actuated, the shutter-close actuator 204 is in its relaxed position, and the centerlines of the shutter apertures 212 coincide with the centerlines of two of the aperture layer apertures 209. In FIG. 2B the shutter assembly 200 has been moved to the closed state and, as such, the shutter-open actuator 202 is in its relaxed position, the shutter-close actuator 204 has been actuated, and the light blocking portions of the shutter 206 are now in position to block transmission of light through the apertures 209 (depicted as dotted lines).

Each aperture has at least one edge around its periphery. For example, the rectangular apertures 209 have four edges. In alternative implementations in which circular, elliptical, oval, or other curved apertures are formed in the aperture layer 207, each aperture may have only a single edge. In some other implementations, the apertures need not be separated or disjoint in the mathematical sense, but instead can be connected. That is to say, while portions or shaped sections of the aperture may maintain a correspondence to each shutter, several of these sections may be connected such that a single continuous perimeter of the aperture is shared by multiple shutters.

In order to allow light with a variety of exit angles to pass through apertures 212 and 209 in the open state, it is advantageous to provide a width or size for shutter apertures 212 which is larger than a corresponding width or size of apertures 209 in the aperture layer 207. In order to effectively block light from escaping in the closed state, it is preferable that the light blocking portions of the shutter 206 overlap the apertures 209. FIG. 2B shows an overlap 216, which in some implementations can be predefined, between the edge of light blocking portions in the shutter 206 and one edge of the aperture 209 formed in the aperture layer 207.

The electrostatic actuators 202 and 204 are designed so that their voltage-displacement behavior provides a bi-stable characteristic to the shutter assembly 200. For each of the shutter-open and shutter-close actuators there exists a range of voltages below the actuation voltage, which if applied while that actuator is in the closed state (with the shutter being either open or closed), will hold the actuator closed and the shutter in position, even after an actuation voltage is applied to the opposing actuator. The minimum voltage needed to maintain a shutter's position against such an opposing force is referred to as a maintenance voltage Vₘ.

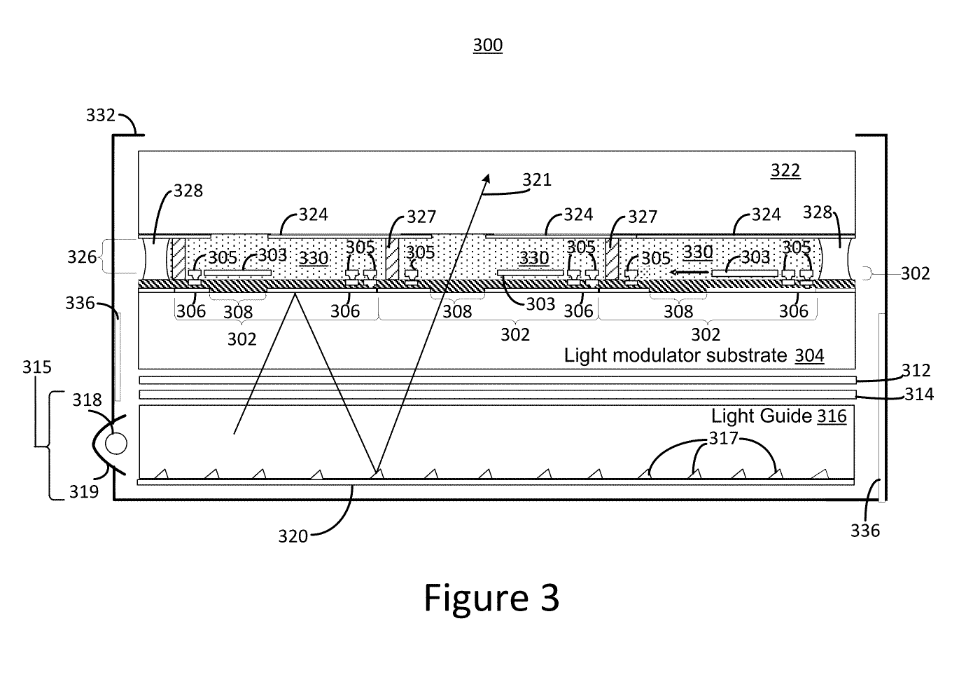

FIG. 3 shows a cross sectional view of an example display apparatus 300 incorporating shutter-based light modulators. As shown, the shutter based light modulators take the form of shutter assemblies 302, similar to the shutter assemblies 200 shown in FIGS. 2A and 2B. Each shutter assembly 302 incorporates a shutter 303 and anchors 305. Not shown are the compliant beam actuators which, when connected between the anchors 305 and the shutters 303, help to suspend the shutters 303 a short distance above the surface. The shutter assemblies 302 are disposed on a transparent substrate 304, such as a substrate made of plastic or glass. A rear-facing reflective layer, reflective film 306, disposed on the substrate 304 defines a plurality of surface apertures 308 located beneath the closed positions of the shutters 303 of the shutter assemblies 302. The reflective film 306 reflects light not passing through the surface apertures 308 back towards the rear of the display apparatus 300.

The display apparatus 300 includes an optional diffuser 312 and/or an optional brightness enhancing film 314 which separate the substrate 304 from a planar light guide 316. The light guide 316 includes a transparent material, such as glass or plastic. The light guide 316 is illuminated by one or more light sources 318. The light guide 316, together with the light sources 318 form a backlight. The light sources 318 can be, for example, and without limitation, incandescent lamps, fluorescent lamps, lasers or light emitting diodes (LEDs). A reflector 319 helps direct light from the light sources 318 towards the light guide 316. A front-facing reflective film 320 is disposed behind the light guide 316, reflecting light towards the shutter assemblies 302.

The light guide 316 includes a set of geometric light redirectors or prisms 317 which re-direct light from the light sources 318 towards the surface apertures 308 and hence toward the front of the display 300. The light redirectors 317 can be molded into the plastic body of light guide 316 with shapes that can be alternately triangular, trapezoidal, or curved in cross section. The density of the prisms 317 generally increases with distance from the light source 318.

A cover plate 322 forms the front of the display apparatus 300. The rear side of the cover plate 322 can be covered with a patterned light blocking layer 324 to increase contrast. The cover plate 322 is supported a predetermined distance away from the shutter assemblies 302 forming a cell gap 326. The cell gap 326 is maintained by mechanical supports or spacers 327 and/or by an adhesive seal 328 attaching the cover plate 322 to the substrate 304.

The adhesive seal 328 seals in a fluid 330. The fluid 330 can have a low coefficient of friction, low viscosity, and minimal degradation effects over the long term. The fluid immerses and surrounds the moving parts of the shutter assemblies 302, and can serve as a lubricant. In some implementations, the fluid 330 is a hydrophobic liquid with a high surface wetting capability. In some implementations, the fluid 330 has a refractive index that is either greater than or less than that of the substrate 304. In some implementations, in order to reduce the actuation voltages, the fluid 330 has a viscosity below about 70 centipoise. In some other implementations, the liquid has a viscosity below about 10 centipoise. Liquids with viscosities below 70 centipoise can include materials with low molecular weights: below 4000 grams/mole, or in some cases below 400 grams/mole. Fluids that may be suitable as the fluid 330 include, without limitation, de-ionized water, methanol, ethanol and other alcohols, paraffins, olefins, ethers, silicone oils, fluorinated silicone oils, or other natural or synthetic solvents or lubricants. Useful fluids can also include polydimethylsiloxanes (PDMS), such as hexamethyldisiloxane and octamethyltrisiloxane, or alkyl methyl siloxanes such as hexylpentamethyldisiloxane. Additional useful fluids include alkanes, such as octane or decane, nitroalkanes, such as nitromethane, and aromatic compounds, such as toluene or diethylbenzene. Further useful fluids include ketones, such as butanone or methyl isobutyl ketone, chlorocarbons, such as chlorobenzene, and chlorofluorocarbons, such as dichlorofluoroethane or chlorotrifluoroethylene. Other suitable fluids include butyl acetate, dimethylformamide, hydro fluoro ethers, perfluoropolyethers, hydro fluoro poly ethers, pentanol, and butanol. Example suitable hydro fluoro ethers include ethyl nonafluorobutyl ether and 2-trifluoromethyl-3-ethoxydodecafluorohexane.

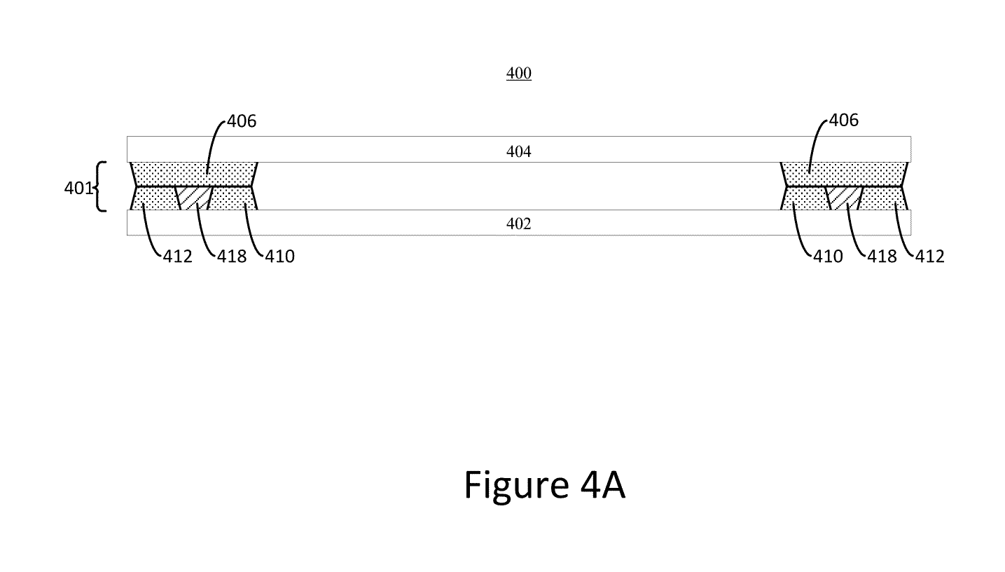

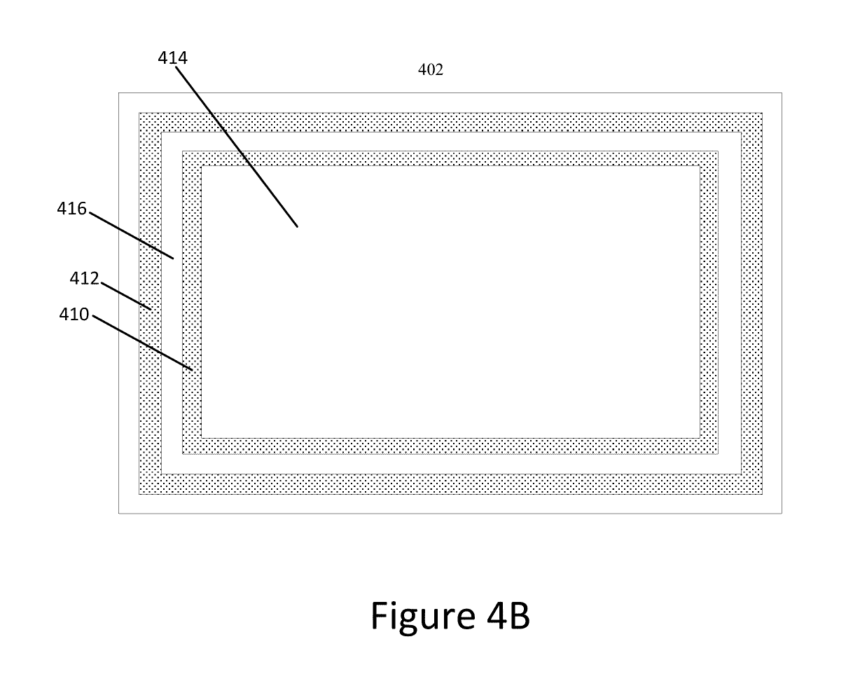

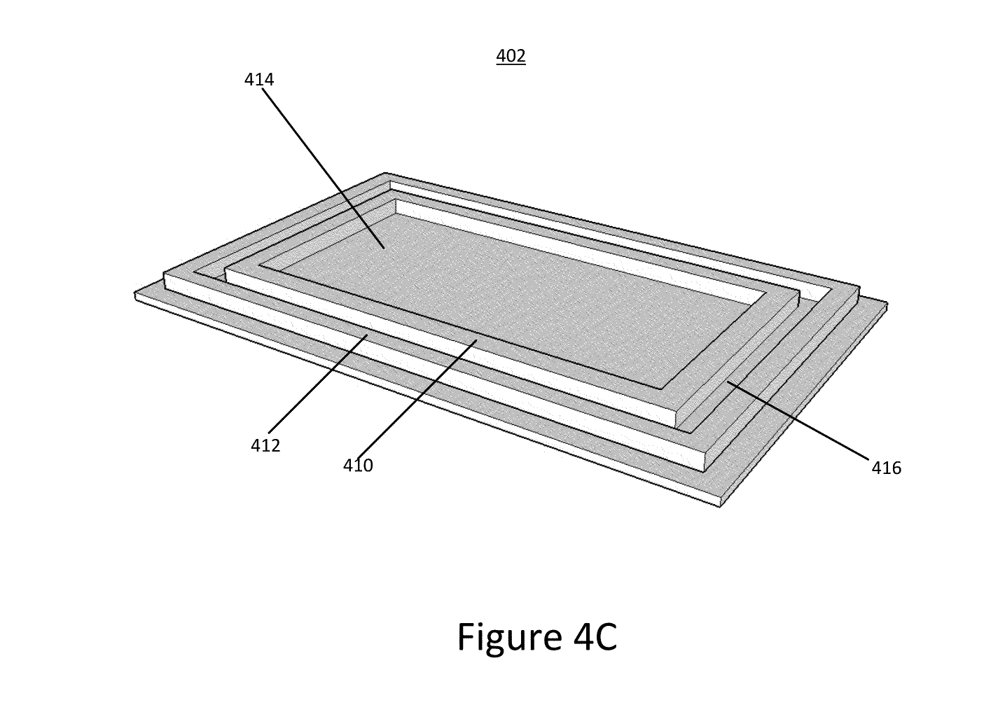

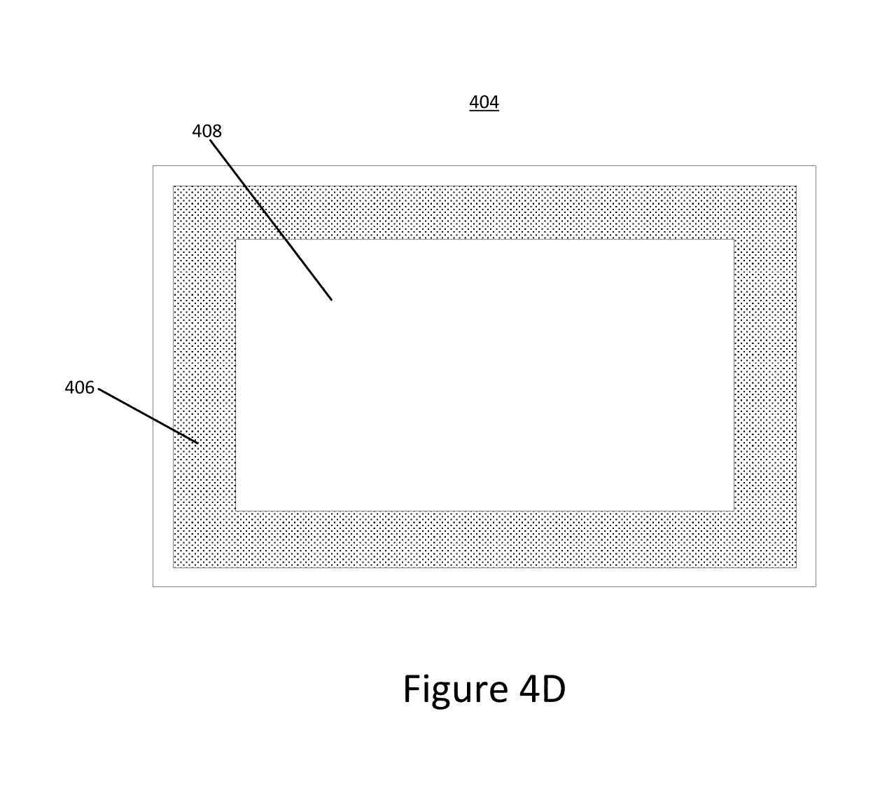

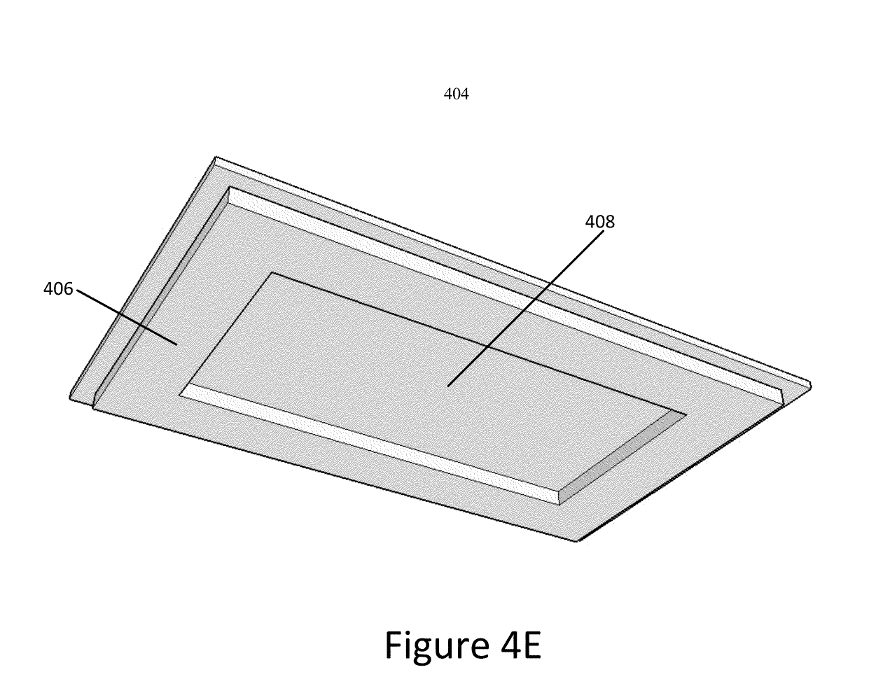

In general, the fluid 330 is carefully selected to have properties that are beneficial to the mechanical and optical performance of the display 300. Maintaining these fluid properties helps improve display reliability and extends the life span of the display 300. In some cases, moisture from the environment in which the display 300 is located can pass through the edge seal 328 and into the fluid 330, thereby altering its mechanical and optical properties and potentially degrading the performance of the display 300. Furthermore, moisture that accumulates on the shutter assemblies 302 may degrade the electrical and/or mechanical performance of the shutter assemblies 302. Reliability of the display 300 can be maintained by preventing moisture from entering the fluid 330. However, some epoxies are permeable to moisture. Therefore, in some implementations, other techniques may be used to achieve a more moisture-resistant or in some cases a moisture impervious edge seal. Several of these techniques are discussed further below in relation to FIGS. 4A-10.

Referring back to FIG. 3, a sheet metal or molded plastic assembly bracket 332 holds the cover plate 322, the substrate 304, the backlight and the other component parts of the display apparatus 300 together around the edges. The assembly bracket 332 is fastened with screws or indent tabs to add rigidity to the combined display apparatus 300. In some implementations, the light source 318 is molded in place by an epoxy potting compound. Reflectors 336 help return light escaping from the edges of the light guide 316 back into the light guide 316. Not depicted in FIG. 3 are electrical interconnects which provide control signals as well as power to the shutter assemblies 302 and the lamps 318.

The display apparatus 300 is referred to as having a MEMS-up configuration, in which the MEMS based light modulators are formed on a front surface of the substrate 304, i.e., the surface that faces toward the viewer. In an alternate implementation, referred to as the MEMS-down configuration, the shutter assemblies are disposed on a substrate separate from the substrate on which the reflective aperture layer is formed. The substrate on which the reflective aperture layer is formed, defining a plurality of apertures, is referred to herein as the aperture plate. In the MEMS-down configuration, the substrate that carries the MEMS-based light modulators takes the place of the cover plate 322 in the display apparatus 300 and is oriented such that the MEMS-based light modulators are positioned on the rear surface of this front substrate, i.e., the surface that faces away from a viewer and toward the light guide 316.

FIGS. 4A-4E show various views of an example display 400 incorporating an alternative perimeter seal 401. FIG. 4A shows a cross-sectional view of the display 400. FIG. 4B shows a plan view of a rear substrate 402 used in the display 400 shown in FIG. 4A. FIG. 4C shows a perspective view of the rear substrate 402 used in the display 400 shown in FIG. 4A. FIG. 4D shows a plan view of a front substrate 404 used in the display 400 shown in FIG. 4A. FIG. 4E shows a perspective view of the front substrate 404 used in the display 400 shown in FIG. 4A. FIGS. 4A-4E are described together below.

Like the display 300 shown in FIG. 3, the display 400 includes a rear substrate 402 and a front substrate 404. In some implementations, the rear substrate 402 can correspond to the substrate 304 shown in FIG. 3, and the front substrate 404 can correspond to the cover sheet 322.

The front substrate 404 includes a single perimeter wall 406 formed around a first image viewing area 408, and the rear substrate 402 includes an inner perimeter wall 410 and an outer perimeter wall 412 both formed around a second image viewing area 414. In practice, shutter assemblies similar to the shutter assemblies 302 shown in FIG. 3 can be located either on the front substrate 404 in the viewing area 408 or on the rear substrate 402 in the image viewing area 414. Additional electronic components, such as drivers and a display controller similar to the drivers 130, 132, and 138 and the controller 134 shown in FIG. 1B may be coupled to the front or rear substrates 404 and 402 outside the perimeter walls 406, 410, and 412. However, to more clearly illustrate the features of the edge seal 401, the shutter assemblies and other electronic components are not shown in FIGS. 4A-4E.

The walls 406, 410, and 412 extend away from the planar surfaces of their respective substrates 404 and 402 and are located on the substrates 404 and 402 such that they are aligned when the substrates 404 and 402 are positioned to oppose each other. The perimeter walls 410 and 412 of the rear substrate 402 are spaced away from one another to define a trench 416. In some implementations, the trench 416 can have a width in the range of about 300 microns to about 1000 microns. The perimeter wall 406 on the front substrate 404 has a width that extends substantially from the outer edge of the outer perimeter wall 412 on the rear substrate 402 substantially to the inner edge of the inner perimeter wall 410 on the rear substrate 402. In some implementations, each of the perimeter walls 410 and 412 on the rear substrate 402 can have a width in the range of about 30 microns to about 60 microns and a height in the range of about 4 microns to about 10 microns. In some implementations, the height of the perimeter wall 406 on the front substrate 404 can be different from the heights of the perimeter walls 410 and 412 formed on the rear substrate 402. The collective height of the perimeter walls 406 and 410 or 406 and 412 ranges from about 5 microns to about 20 microns. The surfaces of the perimeter walls 406, 410, and 412 at the portions of the perimeter walls 406, 410, and 412 farthest from the respective substrates 404 and 402 are substantially planar and parallel to the surfaces of the substrates 404 and 402. As a result, when the substrates 404 and 402 are positioned to oppose one another, the perimeter wall 406 of the front substrate 404 can be placed flush against the perimeter walls 410 and 412 of the rear substrate 402.

The rear substrate 402 and the front substrate 404 can be bonded together by an adhesive material 418, such as an epoxy, that can be deposited into the trench 416 formed between the perimeter walls 408 and 410 of the rear substrate 402. In some implementations, the adhesive material 418 can be electrically conductive or can include electrically conductive particles to form an electrical connection between the front and rear substrates 404 and 402. In some implementations, the adhesive material 418 also includes or is formed from a desiccant.

The adhesive material 418 is deposited into the trench 416 before the substrates 402 and 404 are brought together in an opposing fashion. The adhesive material 418 can then be cured to bond the front substrate 404 to the rear substrate 402. In some implementations, the adhesive material 418 is partially cured before the substrates 402 and 404 are brought together, after which the curing is completed. Both processes result in an edge seal formed by the perimeter walls 406, 410, and 412 as well as the adhesive material 412 around the image viewing areas of the display 400.

In some implementations, the perimeter walls 406, 410, and 412 can be formed from material that is substantially impervious to moisture. For example, the perimeter walls 406, 410, and 412 can be formed from or include one or more layers of amorphous silicon, titanium, silicon nitride, or other materials that are impervious to moisture. In some implementations, one or more layers of such materials coat an inner core (not shown) of the walls 406, 410, and 412 formed from a cured polymer or other mold material used in the fabrication of MEMS display elements. By forming the edge seal 401 by enclosing a moisture-resistant adhesive material 418 (such as epoxy) within the substantially moisture impervious perimeter walls 406, 410, and 412, the edge seal 401 can be made significantly more resistant to moisture than the epoxy edge seal 328 shown in FIG. 3. Because the adhesive material 418 is substantially entirely enclosed within the volume defined by the trench 416 and the perimeter wall 406, the permeability of the adhesive material 418 does not necessarily result in an edge seal that is permeable to moisture. For water moisture to permeate through edge seal 401, it must first pass through any gaps existing between the perimeter wall 406 and the outer perimeter wall 412. The reduced amount of moisture that is able to pass through such gaps, if any, must then pass through the moisture resistant adhesive material 418, before it finds its way through any gaps which may exist between the perimeter wall 406 and inner perimeter wall 410. In general, due to the relatively high surface uniformity of structures fabricated using the thin film processes used to fabricate the walls 406, 410, and 412, such gaps, if any, will likely be very small in size and few in number.

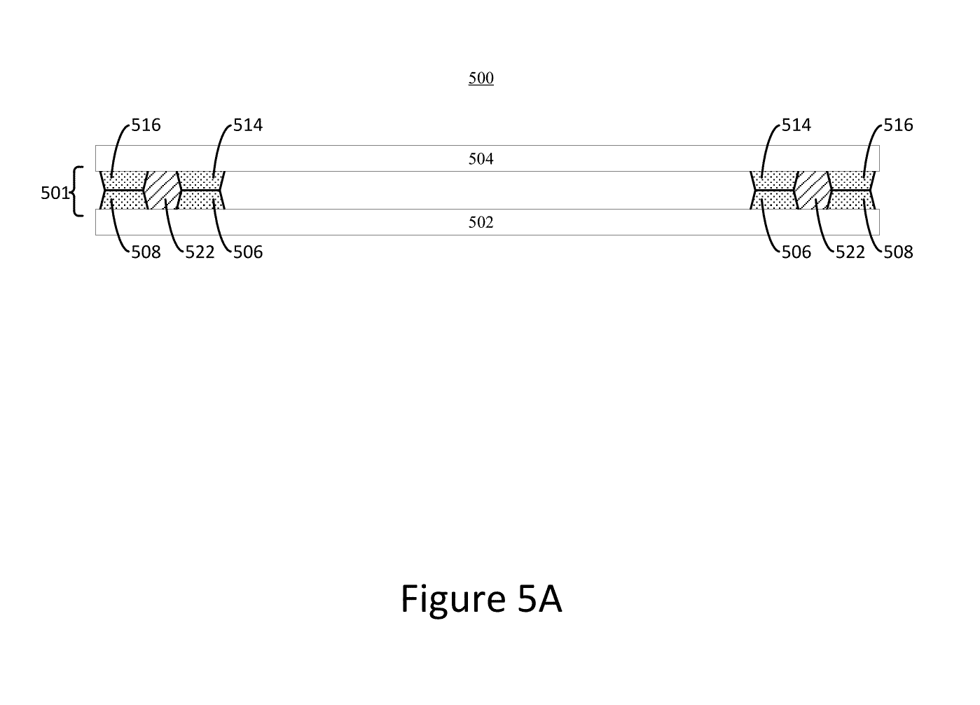

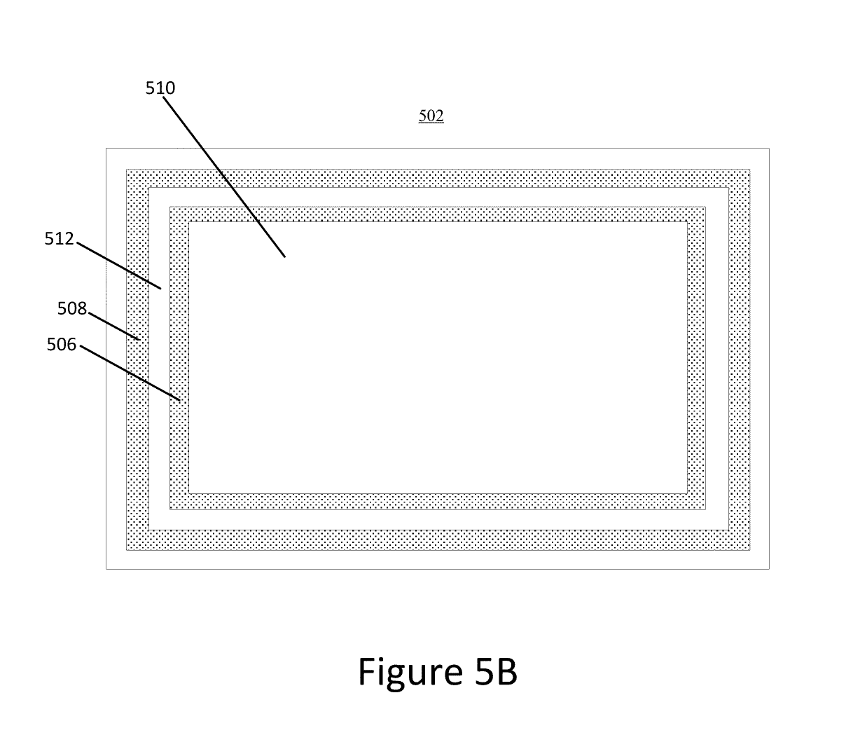

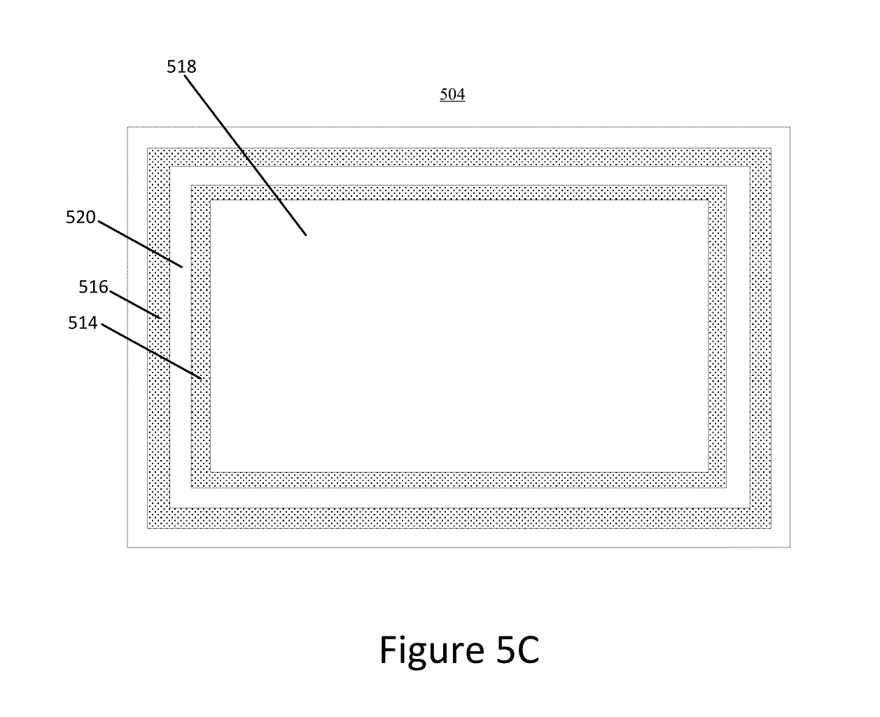

FIGS. 5A-5C show various views of a second example display 500 incorporating another example edge seal 501. FIG. 5A shows a cross-sectional view of the display 500. FIG. 5B shows a plan view of a rear substrate 502 used in the display 500 shown in FIG. 5A. FIG. 5C shows a plan view of a front substrate 504 used in the display 500 shown in FIG. 5A. FIGS. 5A-5C are described together below.

The rear substrate 502 of the example display 500 is similar to the rear substrate 402 shown in FIGS. 4A-4C. The rear substrate 502 includes an inner perimeter wall 506 and an outer perimeter wall 508 both formed around an image viewing area 510. In some implementations, display elements can be positioned in the image viewing area 510. The perimeter walls 506 and 508 define a perimeter trench 512.

The front substrate 504 includes features similar to the features of the rear substrate 502. For example, the front substrate 504 includes an inner perimeter wall 514 and an outer perimeter wall 516, both formed around an image viewing area 518. The perimeter walls 514 and 516 define a perimeter trench 520. In some implementations, the perimeter walls 514 and 516 and the perimeter trench 520 of the front substrate 504 can have dimensions substantially equal to the dimensions of the perimeter walls 506 and 508 and the perimeter trench 512 of the rear substrate 502. Such an arrangement can simplify the process used for manufacturing the display 500 and can help to ensure that the perimeter walls 506 and 508 and the perimeter trench 512 of the rear substrate 502 are aligned with the perimeter walls 514 and 516 and the perimeter trench 520 of the front substrate 504 when the rear substrate 502 is made to oppose the front substrate 504, as shown in FIG. 5A. In some implementations, the perimeter walls 506 and 508 of the rear substrate 502 may have the same widths as the perimeter walls 514 and 516 of the front substrate 504, but may have different heights. In general, the collective heights of the inner perimeter walls 506 and 514 and the outer perimeter walls 508 and 516 are between about 5 microns and about 20 microns. To improve the reliability of the display 500, the perimeter walls 506, 508, 514, and 516 can be formed from or can include a material that is substantially impermeable to moisture, such as the materials described above for the formation of the perimeter walls 406, 410, and 412 shown in FIGS. 4A-4E.

The display 500 is formed by positioning the front substrate 504 so that it opposes the rear substrate 502 with the perimeter walls 514 and 516 of the front substrate 504 contacting the perimeter walls 506 and 508 of the rear substrate 502, respectively. The perimeter trenches 512 and 520 of both the rear substrate 502 and the front substrate 504 are aligned. The trenches 512 and 520 can be filled with an adhesive material 522, such as epoxy, before the substrates 502 and 504 are brought into alignment. The adhesive material 522 can then be cured to bond the rear substrate 502 to the front substrate 504. In some implementations, a sufficient volume of adhesive material 522 is deposited in one of the perimeter trenches 512 or 520 to fill both perimeter trenches when the two are brought together. In some other implementations, each perimeter trench 512 and 520 is filled with an amount of adhesive material 522 sufficient to fill the respective trench. The adhesive material 522 secures the rear substrate 502 and the front substrate 504 in place, while the perimeter walls 506, 508, 514, and 516 provide a substantially moisture-impervious barrier around the viewing area 510 of the rear substrate 502 and the viewing area 528 of the front substrate 504.

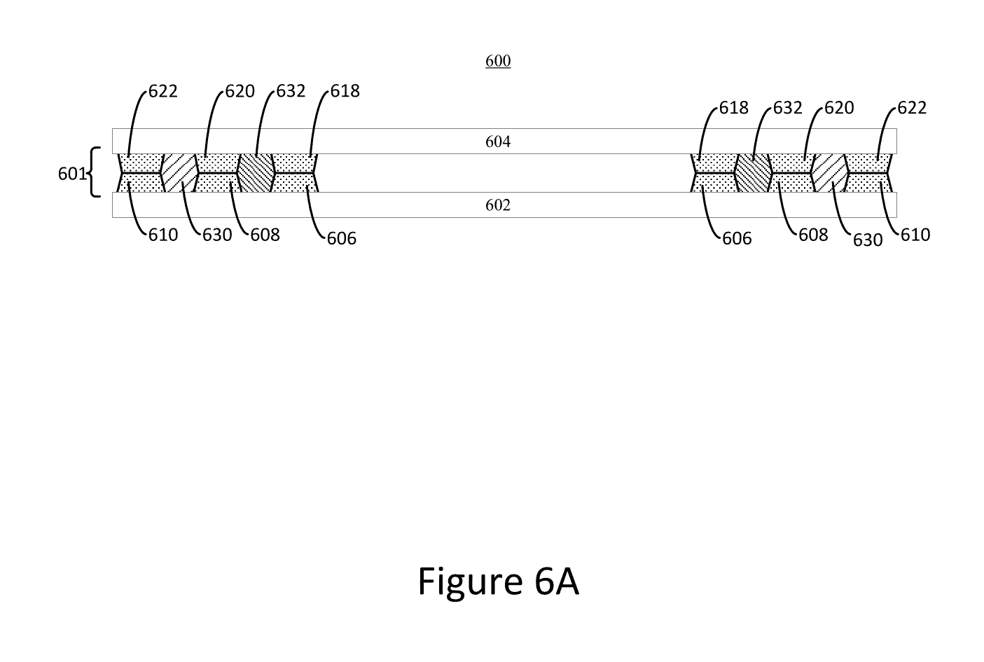

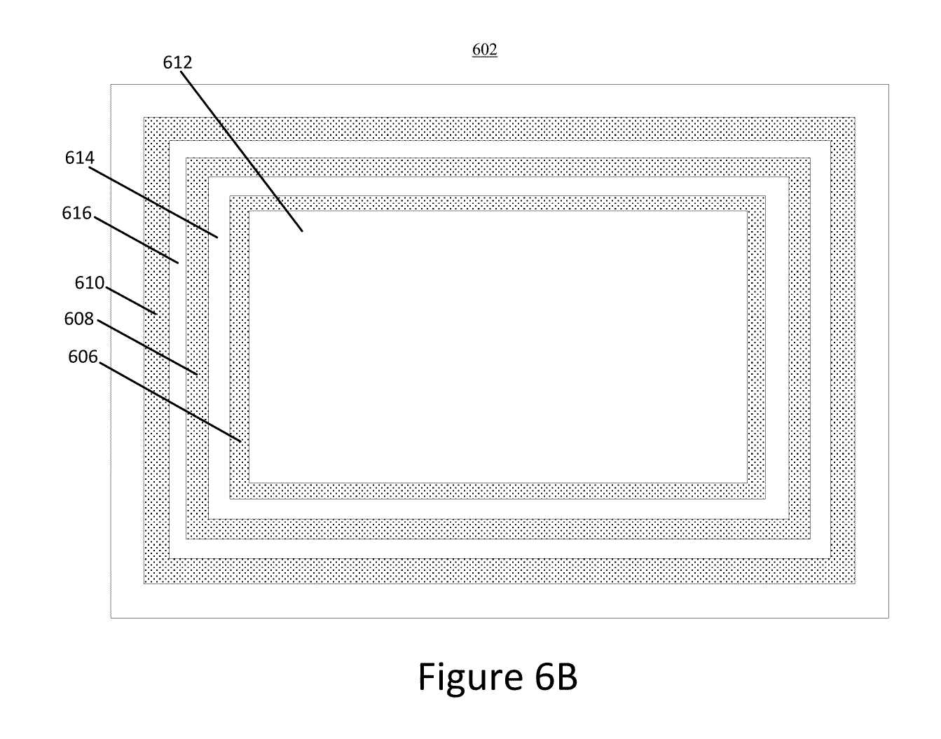

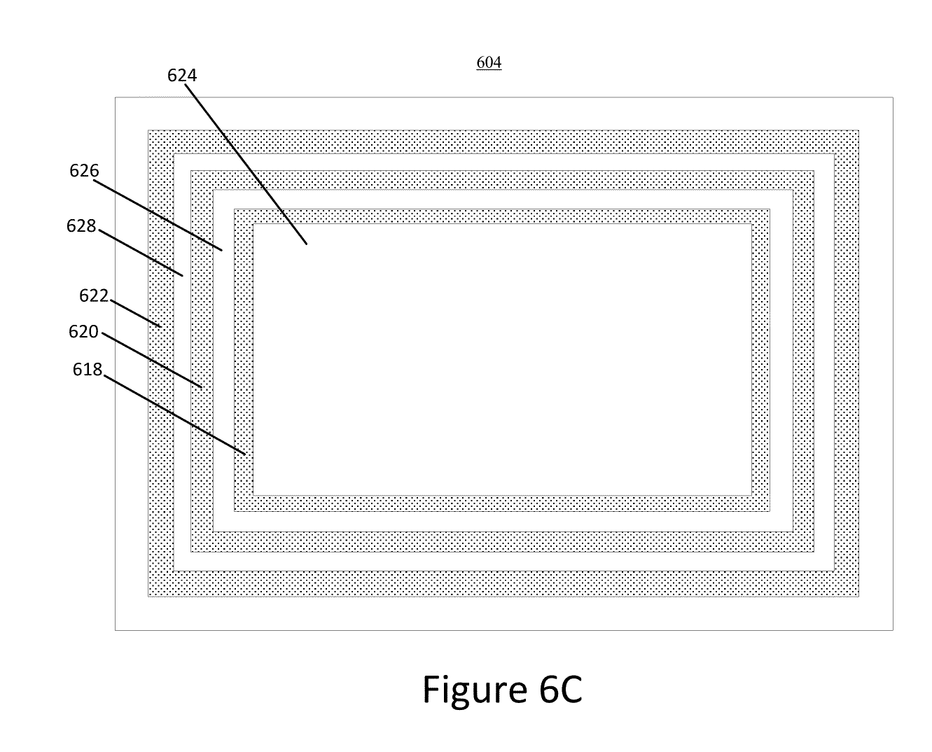

FIGS. 6A-6C show various views of a third example display 600 incorporating another example edge seal 601. The display 600 is formed from a rear substrate 602 and a front substrate 604, each having three perimeter walls. FIG. 6A shows a cross-sectional view of the display 600. FIG. 6B shows a plan view of the rear substrate 602 used in the display 600 shown in FIG. 6A. FIG. 6C shows a plan view of the front substrate 604 used in the display 600 shown in FIG. 6A. FIGS. 6A-6C are described together below.

The rear substrate 602 is similar to the rear substrate 402 shown in FIGS. 4A-4C, except that it has an additional perimeter wall. The rear substrate 602 includes an inner perimeter wall 606, a middle perimeter wall 608, and an outer perimeter wall 610 formed around an image viewing area 612. In some implementations, display elements can be positioned in the image viewing area 612. The perimeter walls 606 and 608 define an inner perimeter trench 614, and the perimeter walls 608 and 610 define an outer perimeter trench 616.

The front substrate 604 includes features similar to the features of the rear substrate 602. As shown in FIG. 6C, the front substrate 604 includes an inner perimeter wall 618, a middle perimeter wall 620, and an outer perimeter wall 622 formed around an image viewing area 624. In some implementations, display elements can be positioned in the image viewing area 624. The perimeter walls 618 and 620 define an inner perimeter trench 626, and the perimeter walls 620 and 622 define an outer perimeter trench 628. In some implementations, the perimeter walls 618, 620, and 622, and the perimeter trenches 626 and 628, of the front substrate 604 can have dimensions substantially equal to the dimensions of the perimeter walls 606, 608, and 610 and the perimeter trenches 614 and 616 of the rear substrate 602. Such an arrangement can simplify the process used for manufacturing the display 600 and can help to ensure that the perimeter walls 606, 608, and 610 of the rear substrate 602 are aligned with the perimeter walls 618, 620, and 622 of the front substrate 604 when the rear substrate 602 is made to oppose the front substrate 604, as shown in FIG. 6A. In some other implementations, the perimeter walls 606, 608, and 610 of the rear substrate 602 may have the same widths as the perimeter walls 618, 620, and 622 of the front substrate 604, but may have different heights. In general, the collective heights of any two opposing perimeter walls (such as perimeter walls 610 and 622, 620 and 608, and 606 and 618) are between about 5 microns and about 20 microns. To improve the reliability of the display 600, the perimeter walls 606, 608, 610, 618, 620, and 622 can be formed from or include a material that is impermeable to moisture. For example, the perimeter walls can be formed from the same materials described above as being suitable for the formation of the perimeter walls 406, 410, and 412 shown in FIGS. 4A-4E.

The display 600 is formed by bringing the front substrate 604 into alignment with the rear substrate 602 so that the perimeter walls 618, 620, and 622 of the front substrate 604 are in contact with the perimeter walls 606, 608, and 610 of the rear substrate 602, respectively. The outer perimeter trenches 616 and 628 can be filled with an adhesive material 630 to bond the rear substrate 602 to the front substrate 604. In some implementations, the inner perimeter trenches 614 and 626 can be filled with a desiccant 632 to absorb any moisture that might permeate through the adhesive material 630 before it passes into the viewing areas 612 and 624. The display 600 can therefore be highly resistant to moisture. Moisture must pass through three sets of perimeter walls, an adhesive material, and a desiccant before entering the image viewing areas 612 and 624. The increased resistance to moisture can make the display 600 more reliable than similar displays that use just an epoxy to form an edge seal.

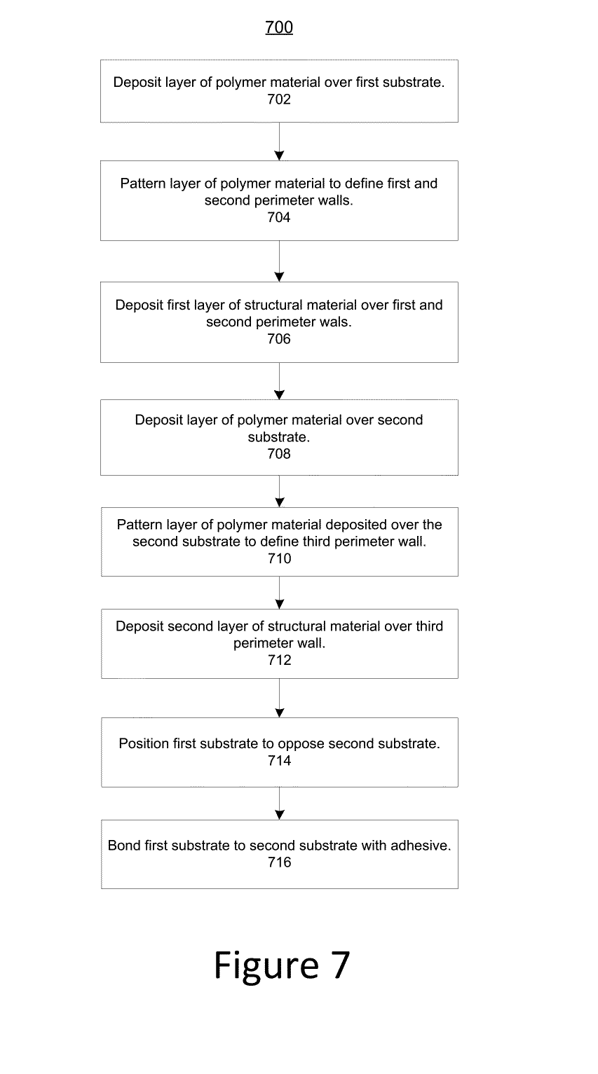

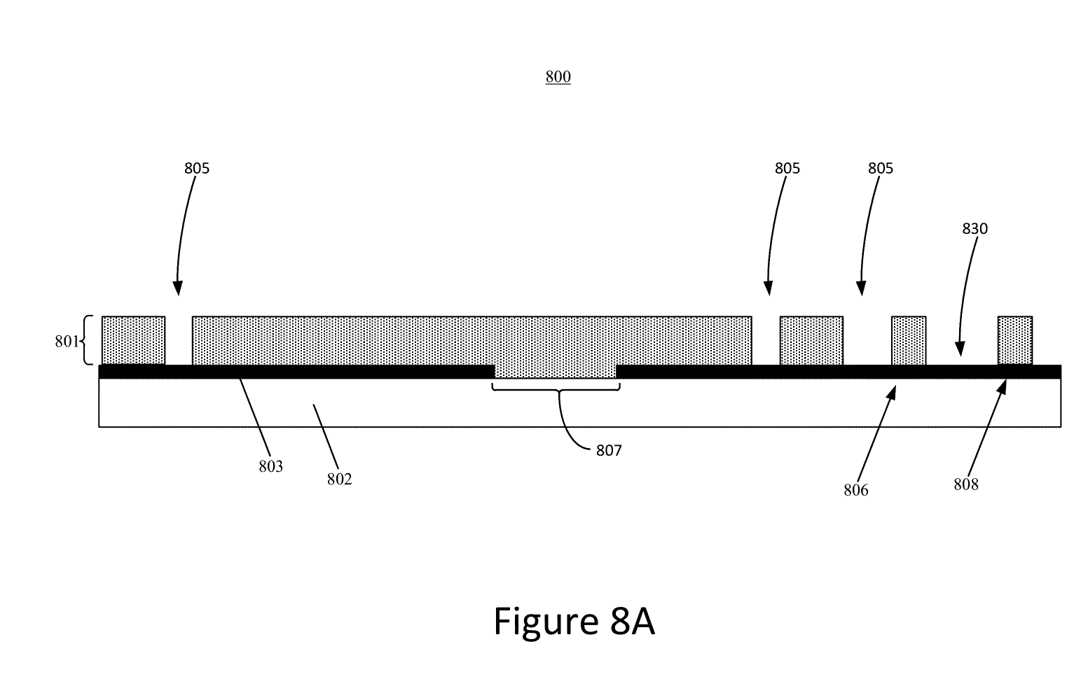

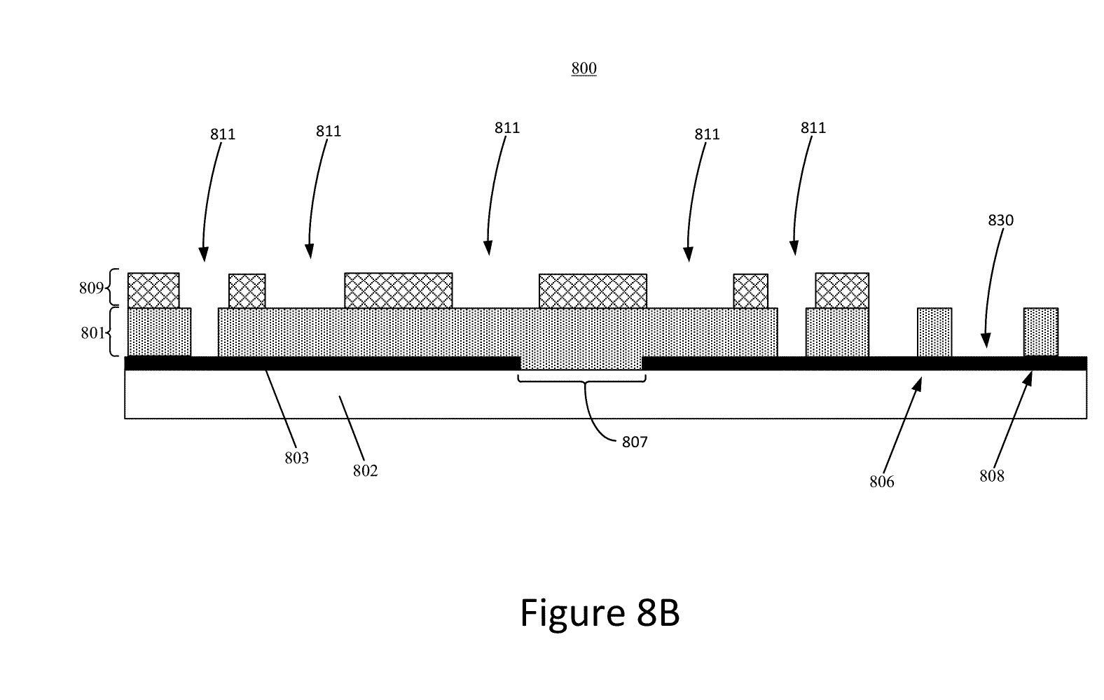

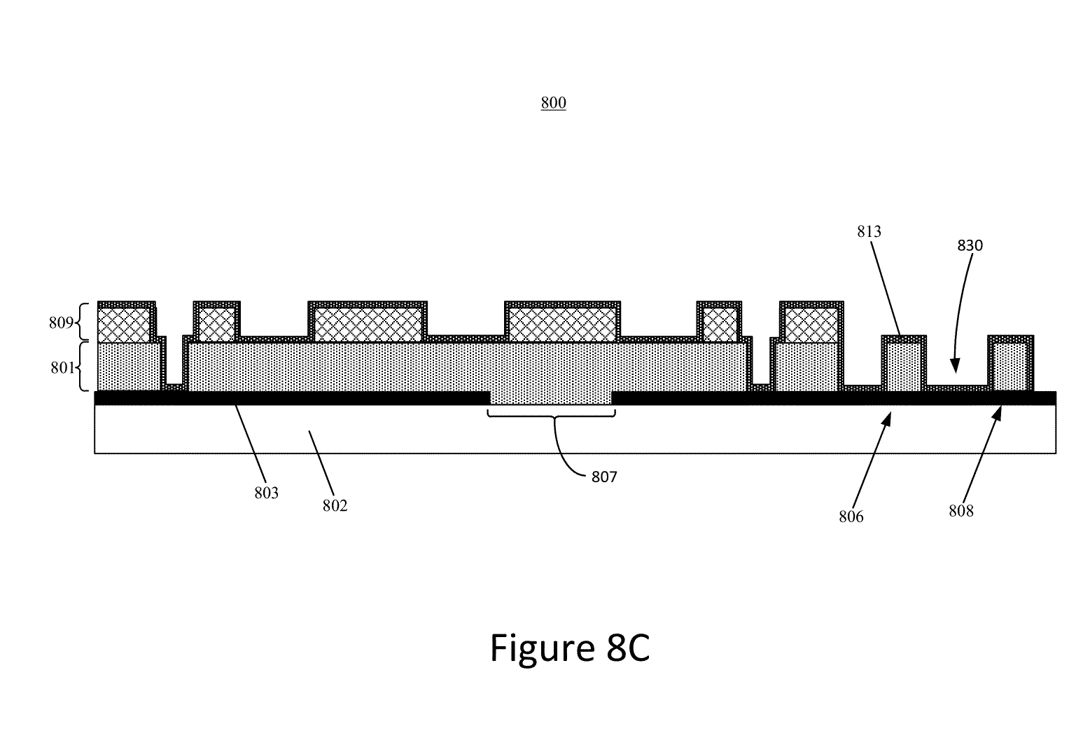

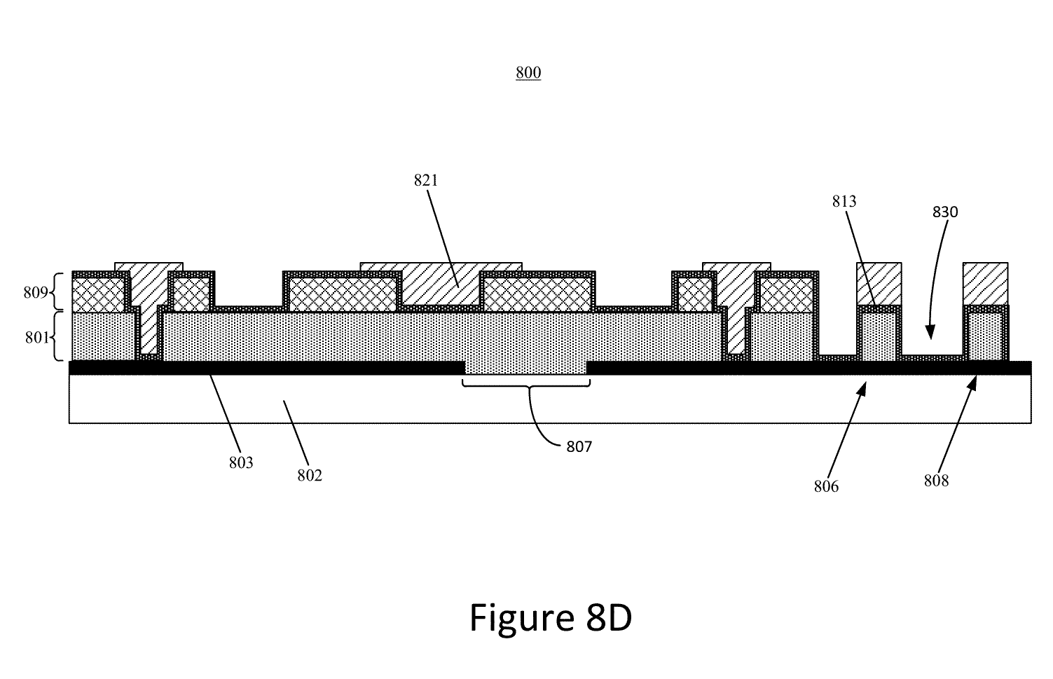

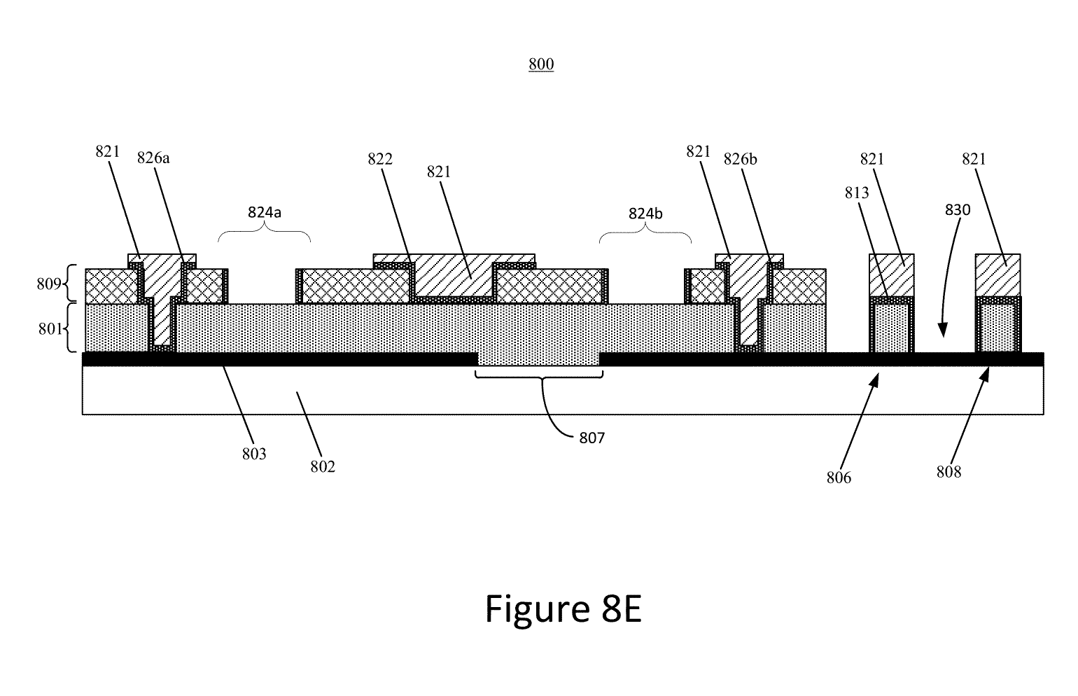

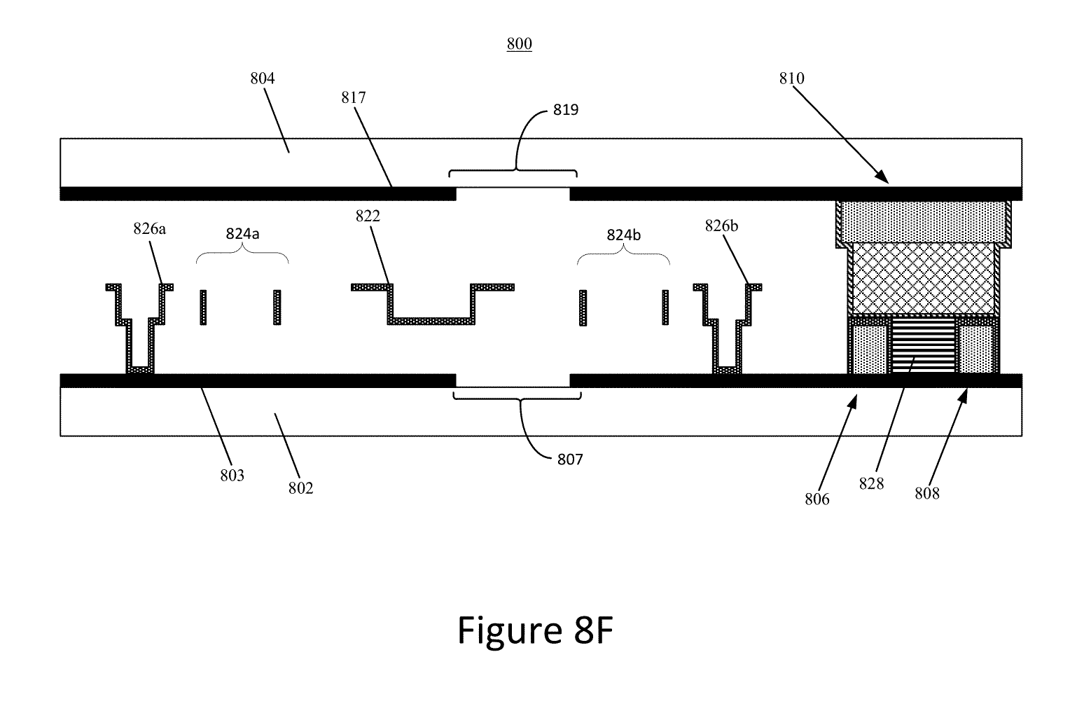

FIG. 7 shows a flow diagram of an example process 700 for manufacturing a display apparatus. For example, the process 700 can be used to manufacture a display incorporating an edge seal similar to the edge seals 401, 501, and 601 shown in FIGS. 4A, 5A, and 6A, respectively. The process 700 includes depositing at least one layer of polymer material over a first substrate (stage 702). The at least one layer of polymer material deposited over the first substrate is patterned to define first and second perimeter walls extending outwards from a surface of the first substrate (stage 704). The first and second perimeter walls define a first perimeter trench. A first layer of structural material is deposited over the at least one layer of polymer material to coat the surfaces of the first and second perimeter walls (stage 706). At least one layer of polymer material is deposited over a second substrate (stage 708). The at least one layer of polymer material deposited over the second substrate is patterned to define a third perimeter wall extending outwards from a surface of the second substrate (stage 710). A second layer of structural material is deposited over the at least one layer of polymer material to coat the surfaces of the third perimeter wall (stage 712). The first and second substrates are positioned such that the first and second perimeter walls of the first substrate are opposed to the third perimeter wall of the second substrate (stage 714). The first substrate is bonded to the second substrate by filling the first perimeter trench with an adhesive material (stage 716). Each of these stages is described below in relation to FIGS. 8A-8F.

FIGS. 8A-8F show cross-sectional views of example stages of construction of an example display 800 according to the manufacturing process 700 shown in FIG. 7. The manufacturing process is also used to form a shutter assembly on a substrate that includes perimeter walls.

The process 700 includes depositing at least one layer of polymer material over a first substrate (stage 702) and patterning the at least one layer of polymer material deposited over the first substrate to define first and second perimeter walls extending outwards from a surface of the first substrate (stage 704). As shown in FIG. 8A, a layer of polymer material 801 is deposited and patterned on top of a light blocking layer 803 previously formed on an underlying substrate 802. The light blocking layer 803 includes an aperture 807. In some other implementations, the layer of polymer material 801 can be deposited directly onto the substrate 802. In some implementations, the polymer material 801 may adhere more strongly to the substrate 802 than to the light blocking layer 803. The first layer of polymer material 801 can be or can include polyimide, polyamide, fluoropolymer, benzocyclobutene, polyphenylquinoxylene, parylene, polynorbornene, polyvinyl acetate, polyvinyl ethylene, and phenolic or novolac resins, or any of the other materials suitable for use as a sacrificial material in thin-film MEMS processing. Depending on the material selected for use as the first layer of polymer material 801, the first layer of polymer material 801 can be patterned using a variety of photolithographic techniques and processes such as direct photo-patterning (for photosensitive sacrificial materials) or chemical or plasma etching through a mask formed from a photolithographically patterned resist. After the patterning, the remaining polymer material is cured, for example by heat or exposure to ultraviolet radiation. The pattern defined in the polymer material 801 creates recesses 805 which partially define a first perimeter wall 806 and a second perimeter wall 808. A trench 830 is defined between the first perimeter wall 806 and the second perimeter wall 808. The recesses 805 can also form portions of a mold for shutter assembly anchors included in display 800 formed in the process 700.

In some implementations, the process 700 can include depositing and patterning additional layers of polymer material to further define the perimeter walls 806 and 808 or other components of the display 800. As shown in FIG. 8B, a second layer of polymer material 809 is deposited and patterned to form recesses 811. Some of the recesses expose the recesses 805 formed in the first layer of polymer material 801. Other recesses serve as a mold for other portions of shutter assemblies formed in the process 700.

The process 700 continues with the deposition of a first layer structural material over the at least one layer of polymer material to coat the surfaces of the first and second perimeter walls (stage 706), as shown in FIG. 8C. A first layer of structural material 813 is deposited over the polymer materials 801 and 809 to coat the surfaces of the perimeter walls 806 and 808. In some implementations, the structural material 813 is deposited using a chemical vapor deposition (CVD) process or a plasma-enhanced CVD (PECVD) process. In some implementations, the first structural material 813 can include one or more layers of a material that is substantially impervious to moisture, such as amorphous silicon (Si), titanium (Ti), silicon nitride (Si₃N₄), aluminum (Al), copper (Cu), nickel (Ni), chromium (Cr), molybdenum (Mo), tantalum (Ta), niobium (Nb), neodymium (Nd), or alloys thereof. In some implementations, the structural material 813 is deposited to a thickness of less than about 2 microns.

The process 700 can include patterning the structural material 813 (not shown in FIG. 7), as shown in FIGS. 8D and 8E. First, a photoresist mask 821 is deposited on the structural material 813. The photoresist 821 is then patterned. The pattern developed into the photoresist is selected such that, after a subsequent etch stage (shown in FIG. 8E), the remaining structural material 813 forms the light blocking portion of a shutter 822, along with actuators 824a and 824b and anchors 826a and 826b, similar to the shutter 206, actuators 202 and 204 and anchors 208, shown in FIGS. 2A and 2B. The etch of the structural material 813 can be an anisotropic etch, an isotropic etch, or a combination of anisotropic and isotropic etches. In some implementations, the shutter 822, the actuators 824, and the anchors 826 can be formed using multiple patterning and etching steps. Once the structural components of the display 800 are formed, the polymer material can be removed. In some implementations, the polymer material can be removed using standard MEMS release methodologies, including, for example, exposing the mold to an oxygen plasma, wet chemical etching, or vapor phase etching.

The process 700 includes depositing at least one layer of polymer material over a second substrate (stage 708). The at least one layer of polymer material deposited over the second substrate is patterned to define a third perimeter wall extending outwards from a surface of the second substrate (stage 710). A second layer of structural material is deposited over the at least one layer of polymer material to coat the surfaces of the third perimeter wall (stage 712). States 708-712 can be carried out on a second substrate in a manner similar to how stages 702-706 are carried out on the first substrate 802, as described above and shown on the first substrate 802 in FIGS. 8A-8C. The second substrate 804, third perimeter wall 810, and second layer of structural material 815 are shown in FIG. 8F. The second substrate 804 also includes a light blocking layer 817 having an aperture 819 aligned with the aperture 807 of the first substrate 802.

The process 700 includes positioning the first and second substrate such that the first and second perimeter walls of the first substrate are opposed to the third perimeter wall of the second substrate (stage 714). As shown in FIG. 8F, the first substrate 802 is substantially parallel to the second substrate 804 and the third perimeter wall 810 of the second substrate 804 is brought into contact with the first perimeter wall 806 and the second perimeter wall 808 of the first substrate 802. The process 700 can also include bonding the first substrate to the second substrate by filling the first perimeter trench with an adhesive material, such as an epoxy (stage 716). The adhesive material 828 is shown filling the perimeter trench, which is enclosed between the first perimeter wall 806, the second perimeter wall 808, and the third perimeter wall 810. The result, shown in FIG. 8F, also includes the light blocking portions 822 of the shutter, the actuators 824, and the anchors 826. The light blocking portion 822 is positioned in a neutral position with respect to the apertures 807 and 819.

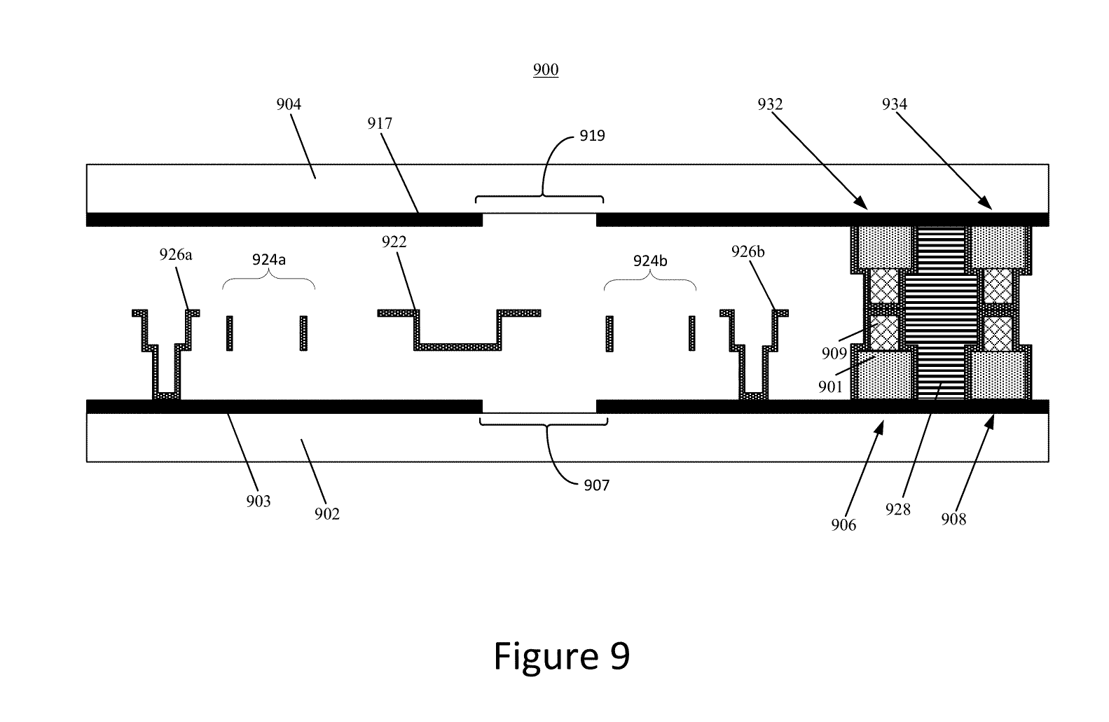

As discussed above, each substrate may include any number of perimeter walls and the height of the perimeter walls on each substrate can vary. FIG. 9 shows a second example of a display 900 that can be manufactured according to a process similar to the process 700 shown in FIG. 7. FIG. 9 depicts the display 900 after the front substrate 904 has been bonded to the rear substrate 902. In FIGS. 8 and 9, like reference numerals refer to like elements. As shown in FIG. 9, the perimeter walls 906 and 908 of the first substrate 902 extend up to the level of the second polymer material 909. The second substrate 904 includes two perimeter walls 932 and 934. The first substrate 902 is bonded to the second substrate 904 by filling the space between the perimeter walls 906, 908, 932, and 934 with an adhesive material 928, such as an epoxy.

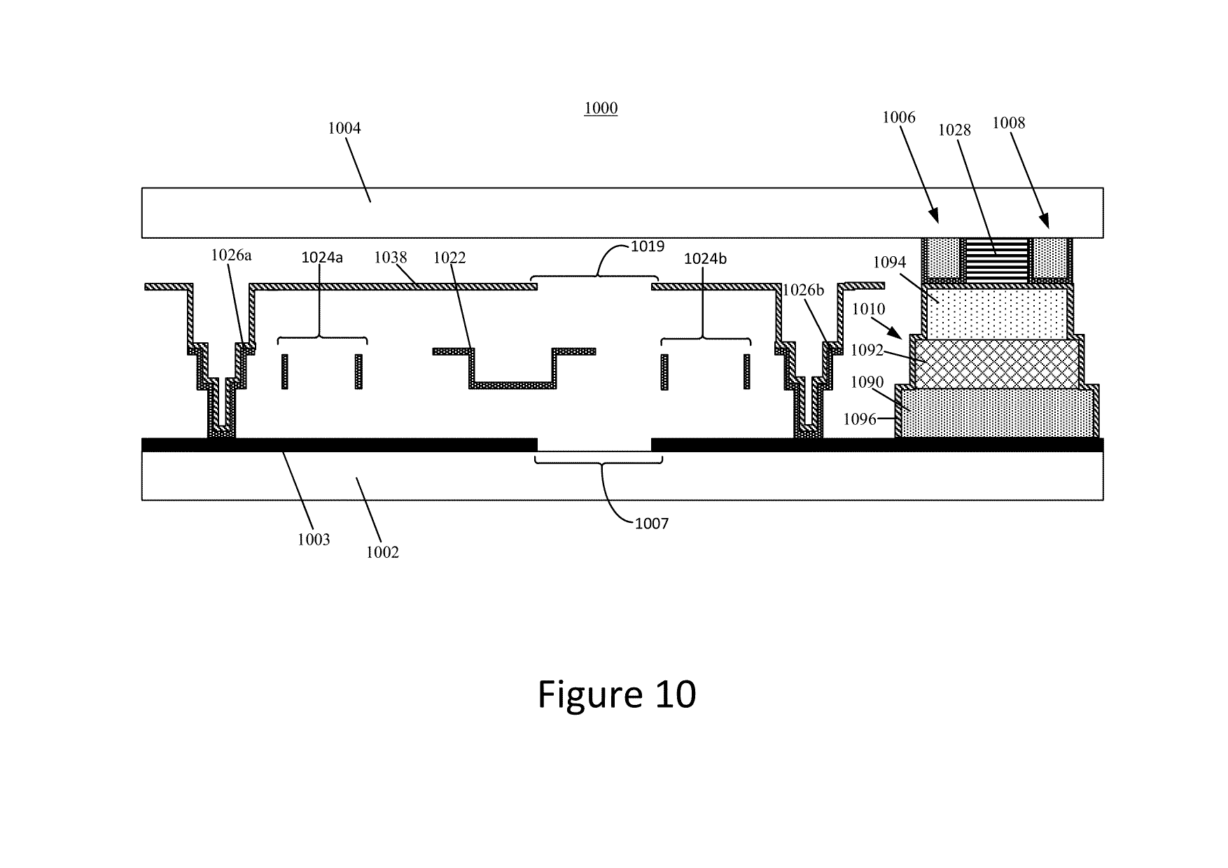

FIG. 10 shows a third example of a display 1000 that can be manufactured according to a process similar to the process 700 shown in FIG. 7. FIG. 10 depicts the display 1000 at the stage after the front substrate 1004 has been bonded to the rear substrate 1002. In FIGS. 8 and 10, like reference numerals refer to like elements. The display 1000 is formed using three layers of polymer material 1090, 1092, and 1094 deposited on the rear substrate 1002, with the third layer 1094 used to form a mold for an elevated aperture layer 1038. The elevated aperture layer 1038 includes an aperture 1019 aligned with the aperture 1007 formed over the rear substrate 1002. The front substrate 1004 does not include a light blocking layer because that purpose is served by the elevated aperture layer 1038. The rear substrate 1002 includes a single perimeter wall 1010. The perimeter wall 1010 is fabricated by coating the three layers of polymer material 1090, 1092, and 1094 with a moisture-impervious structural material 1096. Because the perimeter wall 1010 formed on the rear substrate 1002 rises up to the height of the EAL 1038, the perimeter walls 1006 and 1008 of the front substrate 1004 can extend only to a first level of polymer material to support the front substrate 1004 above the shutter 1022. This can simplify the process for manufacturing the front substrate 1004 and its associated perimeter walls 1006 and 1008. The rear substrate 1002 is bonded to the front substrate 1004 by filling the space between the perimeter walls 1006, 1008, and 1010 with an adhesive material 1028, such as an epoxy.

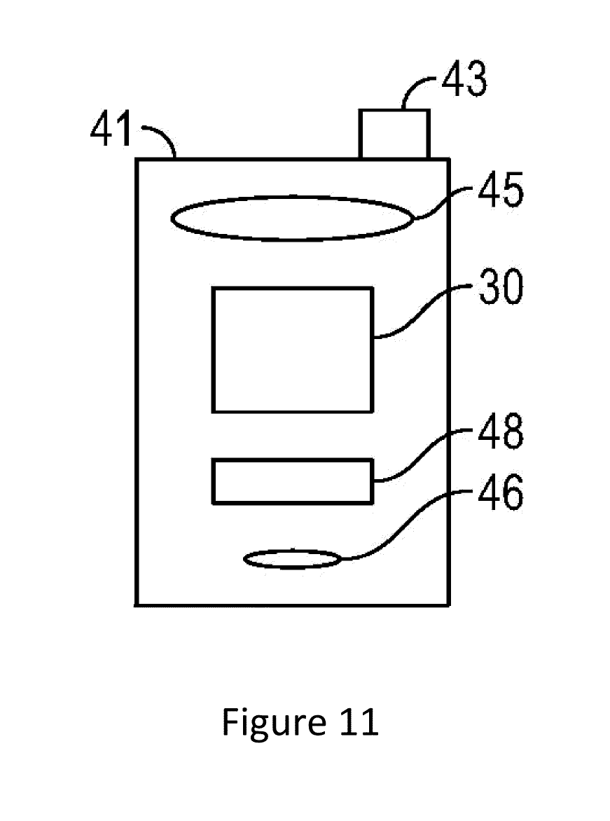

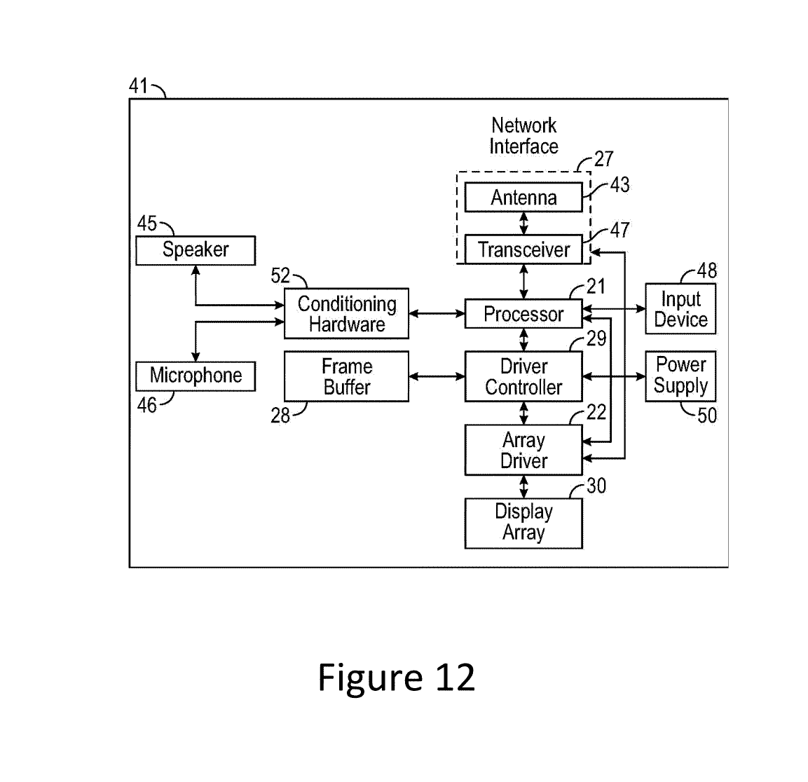

FIGS. 11 and 12 show system block diagrams of an example display device 40 that includes a plurality of display elements. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, electroluminescent (EL) displays, OLED, super twisted nematic (STN) display, LCD, or thin-film transistor (TFT) LCD, or a non-flat-panel display, such as a cathode ray tube (CRT) or other tube device. In addition, the display 30 can include a mechanical light modulator-based display, as described herein.

The components of the display device 40 are schematically illustrated in FIG. 12. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 32. The conditioning hardware 32 may be configured to condition a signal (such as filter or otherwise manipulate a signal). The conditioning hardware 32 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIG. 11, can be configured to function as a memory device and be configured to communicate with the processor 21. In some implementations, a power supply 30 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1×EV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 3G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 32 may include amplifiers and filters for transmitting signals to the speaker 45, and for receiving signals from the microphone 46. The conditioning hardware 32 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements. In some implementations, the array driver 22 and the display array 30 are a part of a display module. In some implementations, the driver controller 29, the array driver 22, and the display array 30 are a part of the display module.

In some implementations, the driver controller 29, the array driver 22, and the display array 30 are appropriate for any of the types of displays described herein. For example, the driver controller 29 can be a conventional display controller or a bi-stable display controller (such as a mechanical light modulator display element controller). Additionally, the array driver 22 can be a conventional driver or a bi-stable display driver (such as a mechanical light modulator display element controller). Moreover, the display array 30 can be a conventional display array or a bi-stable display array (such as a display including an array of mechanical light modulator display elements). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40.

The power supply 30 can include a variety of energy storage devices. For example, the power supply 30 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 30 also can be a renewable energy source, a capacitor, or a solar cell, including a plastic solar cell or solar-cell paint. The power supply 30 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, e.g., a combination of a DSP and a microprocessor, a plurality of microprocessors, one or more microprocessors in conjunction with a DSP core, or any other such configuration. In some implementations, particular processes and methods may be performed by circuitry that is specific to a given function.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of any device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An apparatus comprising:
a first substrate including a first planar surface including a first image viewing area;
a first perimeter wall formed around a perimeter of the first image viewing area and extending away from the first planar surface;
a second perimeter wall formed around a perimeter of the first image viewing area and extending away from the first planar surface, the first and second perimeter walls defining a first perimeter trench surrounding the first image viewing area of the first substrate;
a second substrate comprising a second planar surface opposing the first planar surface of the first substrate and including a second image viewing area aligned with the first image viewing area of the first substrate;
a third perimeter wall formed around a perimeter of the second image viewing area and extending away from the second planar surface; and
an adhesive material filling the first perimeter trench and bonding the first substrate to the second substrate.

2. The apparatus of claim 1, wherein the first perimeter wall and the second perimeter wall include a cured polymer material coated with a material that is substantially impervious to moisture.

3. The apparatus of claim 1, wherein the first perimeter wall and second perimeter wall include one or more of amorphous silicon, aluminum, titanium, and a dielectric material.

4. The apparatus of claim 1, further comprising a plurality of microelectromechanical systems (MEMS) display elements fabricated on the first substrate, wherein the first perimeter wall and the MEMS display elements are formed of at least one common material.

5. The apparatus of claim 1, further comprising:
a fourth perimeter wall, on the second substrate, around the perimeter of the second image viewing area and extending away from the second planar surface, the third perimeter wall and the fourth perimeter wall defining a second perimeter trench surrounding the second image viewing area of the second substrate, wherein the first perimeter trench of the first substrate is aligned with the second perimeter trench of the second substrate; and wherein the adhesive material also fills the second perimeter trench.

6. The apparatus of claim 5, further comprising:
a fifth perimeter wall, on the first substrate, spaced away from the second perimeter wall and extending away from the first planar surface, the second and fifth perimeter walls defining a third perimeter trench surrounding the first image viewing area of the first substrate; and
a sixth perimeter wall, on the second substrate, spaced away from the fourth perimeter wall and extending away from the first planar surface, the fourth and sixth perimeter walls defining a fourth perimeter trench surrounding the first image viewing area of the first substrate; wherein, the third perimeter trench on the first substrate is aligned with the fourth perimeter trench on the second substrate.

7. The apparatus of claim 6, further comprising a desiccant material filling the third and fourth perimeter trenches.

8. The apparatus of claim 1, wherein each of the first, second, and third perimeter walls has a height in the range of about 4 microns to about 10 microns.

9. The apparatus of claim 1, wherein each of the first, second, and third perimeter walls has a width in the range of about 30 microns to about 60 microns.

10. The apparatus of claim 1, wherein the first perimeter trench has a width in the range of about 300 microns to about 1000 microns.

11. The apparatus of claim 1, further comprising:
a display including the apparatus;
a processor that is capable of communicating with the display, the processor being capable of processing image data; and
a memory device that is capable of communicating with the processor.

12. The apparatus of claim 11, further comprising:
a driver circuit capable of sending at least one signal to the display; and
a controller capable of sending at least a portion of the image data to the driver circuit.

13. The apparatus of claim 11, further comprising:
an image source module capable of sending the image data to the processor, wherein the image source module includes at least one of a receiver, transceiver, and transmitter.

14. The apparatus of claim 11, further comprising:
an input device capable of receiving input data and communicating the input data to the processor.

15. A method of manufacturing a display apparatus, the method comprising:
depositing at least one layer of polymer material over a first substrate;
patterning the at least one layer of polymer material deposited over the first substrate to define a first perimeter wall extending outwards from a surface of the first substrate and surrounding a first image viewing area on the first substrate and a second perimeter wall extending outwards from the surface of the first substrate and surrounding the first image viewing area, the first and second perimeter walls defining a first perimeter trench surrounding the first image viewing area of the first substrate;
depositing a first layer of structural material over the at least one layer of polymer material such that the structural material coats the surfaces of the first and second perimeter walls, wherein the structural material is substantially impervious to moisture;
depositing at least one layer of polymer material over a second substrate;
patterning the at least one layer of polymer material deposited over the second substrate to define a third perimeter wall extending outwards from a surface of the second substrate and surrounding a second image viewing area on the second substrate;
depositing a second layer of structural material over the at least one layer of polymer material deposited over the second substrate such that the structural material coats the surfaces of the third perimeter wall, wherein the structural material is substantially impervious to moisture;
positioning the first substrate and the second substrate such that the first and second perimeter walls of the first substrate are opposed to the third perimeter wall of the second substrate; and
bonding the first substrate to the second substrate by filling the first perimeter trench with an adhesive material.

16. The method of claim 15, further comprising forming a plurality of display elements over the first viewing area of the first substrate.

17. The method of claim 15, further comprising:
patterning the at least one layer of polymer material deposited over the second substrate to define a fourth perimeter wall extending outwards from the surface of the second substrate and surrounding the second image viewing area on the second substrate, the third perimeter wall and the fourth perimeter wall defining a second perimeter trench surrounding the second image viewing area;
positioning the first substrate and the second substrate such that the first perimeter trench is aligned with the second perimeter trench; and
filling the first perimeter trench and the second perimeter trench with the adhesive material.

18. The method of claim 17, further comprising:
patterning the at least one layer of polymer material deposited over the first substrate to define a fifth perimeter wall extending outwards from the surface of the first substrate and surrounding the first image viewing area on the first substrate, the fifth perimeter wall and the second perimeter wall defining a third perimeter trench surrounding the first image viewing area;
patterning the at least one layer of polymer material deposited over the second substrate to define a sixth perimeter wall extending outwards from the surface of the second substrate and surrounding the second image viewing area on the second substrate, the sixth perimeter wall and the fourth perimeter wall defining a fourth perimeter trench surrounding the second image viewing area;
positioning the first substrate and the second substrate such that the third perimeter trench is aligned with the fourth perimeter trench; and
filling the third perimeter trench and the fourth perimeter trench with a desiccant.
